(19) United States
(12) Patent Application Publication
(10) Pub. No.: US 2026/0338893 A1
(43) Pub. Date: Oct. 29, 2026

(54) METHODS AND SYSTEMS FOR OBTAINING A COMPONENT FRACTION FOR CHEMICAL SHIFT IMAGING

(71) Applicant: SHANGHAI UNITED IMAGING HEALTHCARE CO., LTD., Shanghai (CN)

(72) Inventor: Yongquan YE, Houston, TX (US)

(73) Assignee: SHANGHAI UNITED IMAGING HEALTHCARE CO., LTD., Shanghai (CN)

(21) Appl. No.: 19/654,429

(22) Filed: Apr. 21, 2026

(30) Foreign Application Priority Data
Apr. 25, 2025 (CN) 202510535774.2

(51) Int. Cl. G01R 33/48; G01R 33/56

(52) U.S. Cl. CPC G01R 33/4828; G01R 33/5608

(57) ABSTRACT

Methods and systems for obtaining a component fraction for chemical shift imaging are provided. The methods include obtaining a first echo signal and a second echo signal of an object to be imaged that correspond to a first echo time and a second echo time, respectively. The methods include determining a first component phase difference based on the first echo time and a precession frequency difference between a first target component and a second target component, and determining a second component phase difference based on a second echo time and the precession frequency difference. The method further includes determining a first target component fraction and a second target component fraction based on a signal intensity and a phase of the first echo signal, a signal intensity and a phase of the second echo signal, the first component phase difference, and the second component phase difference.

### CROSS-REFERENCE TO RELATED APPLICATIONS

This application claims the priority of Chinese Patent Application No. 202510535774.2, filed on Apr. 25, 2025, the contents of which are hereby incorporated by reference.

### TECHNICAL FIELD

The present disclosure generally relates to the field of medical imaging, and in particular to methods and systems for obtaining a component fraction for chemical shift imaging.

### BACKGROUND

Conventional magnetic resonance chemical shift imaging (CSI) methods are categorized into two classes. The first class involves excitation and acquisition of signals from a single tissue component (e.g., water or fat), such as fat saturation techniques, water excitation techniques, inversion recovery techniques, etc. The second class involves excitation and acquisition of signals from multiple tissue components, such as water-fat separation techniques, fat fraction quantification techniques, etc. However, the second class of methods described above requires the application of a regional similarity assumption or a region-growing algorithm, which may result in water-fat signal swapping—a phenomenon in magnetic resonance imaging in which water signals and fat signals are in correctly distinguished during pixel signal type classification. In addition, to accurately target the in-phase echo time and out-of-phase echo time of water and fat signals, constraints are often imposed on imaging parameters, which in turn compromises scan time or the resolution of the acquired images.

Therefore, it is desirable to provide a method and system for obtaining a component fraction for chemical shift imaging that can both avoid water-fat signal swapping and ensure scanning efficiency and the resolution of reconstructed images.

### SUMMARY

One or more embodiments of the present disclosure provide a method for obtaining a component fraction for chemical shift imaging. The method includes obtaining one or more echo signal pairs of an object to be imaged. Each echo signal pair includes a first echo signal and a second echo signal, the first echo signal corresponds to a first echo time, the second echo signal corresponds to a second echo time, and the second echo time is different from the first echo time. The method further includes performing processing on at least one echo signal pair of the one or more echo signal pairs to obtain at least one of a first target component fraction or a second target component fraction corresponding to the at least one echo signal pair. The processing includes determining a first component phase difference based on the first echo time and a precession frequency difference between a first target component signal and a second target component signal of the at least one echo signal pair. The first component phase difference reflects a phase difference between the first target component signal and the second target component signal at the first echo time. The processing includes determining a second component phase difference based on the second echo time and the precession frequency difference. The second component phase difference reflects a phase difference between the first target component signal and the second target component signal at the second echo time. The processing further includes determining the at least one of the first target component fraction or the second target component fraction based on a signal intensity and a phase of the first echo signal, a signal intensity and a phase of the second echo signal, the first component phase difference, and the second component phase difference.

In some embodiments, the first echo time is closer to an in-phase echo time than the second echo time, and the second echo time is closer to an opposed-phase echo time than the first echo time. The in-phase echo time is an in-phase echo time of the first target component signal and the second target component signal, and the opposed-phase echo time is an opposed-phase echo time of the first target component signal and the second target component signal.

In some embodiments, the determining the at least one of the first target component fraction or the second target component fraction based on a signal intensity and a phase of the first echo signal, a signal intensity and a phase of the second echo signal, the first component phase difference, and the second component phase difference includes determining an echo signal phase difference based on a difference between the phase of the first echo signal and the phase of the second echo signal; determining a first relational expression of a signal intensity of the second target component signal and a target phase difference based on the signal intensity of the first echo signal, the signal intensity of the second echo signal, the echo signal phase difference, the first component phase difference, and the second component phase difference, wherein the target phase difference is a phase difference between the first target component signal and the first echo signal at the first echo time; determining a signal intensity constraint condition of the first target component signal and the second target component signal based on the signal intensity of the first echo signal, the signal intensity of the second echo signal, the first component phase difference, and the second component phase difference; determining a relationship between a degree to which the signal intensity of the second target component signal satisfies the signal intensity constraint condition and the target phase difference based on the first relational expression and the signal intensity constraint condition; determining a target value of the target phase difference that maximizes the degree to which the signal intensity of the second target component signal satisfies the signal intensity constraint condition; and determining the first target component fraction and the second target component fraction based on the target value of the target phase difference.

In some embodiments, the determining a signal intensity constraint condition of the first target component signal and the second target component signal based on the signal intensity of the first echo signal, the signal intensity of the second echo signal, the first component phase difference, and the second component phase difference includes determining a sum and difference of signal intensities of the first target component signal and the second target component signal based on the signal intensity of the first echo signal, the signal intensity of the second echo signal, the first component phase difference, and the second component phase difference, wherein the signal intensity constraint condition includes the sum and difference of signal intensities.

In some embodiments, the determining a relationship between a degree to which the signal intensity of the second target component signal satisfies the signal intensity constraint condition and the target phase difference based on the first relational expression and the signal intensity constraint condition includes determining a second relational expression of a difference between the signal intensity of the first target component signal and the signal intensity of the second target component signal and the target phase difference based on the first relational expression and the sum of signal intensities; and determining a discrepancy function, characterized by the target phase difference, between the difference between the signal intensity of the first target component signal and the signal intensity of the second target component signal and the difference of signal intensities based on the second relational expression and the difference of signal intensities.

In some embodiments, the determining a target value of the target phase difference that maximizes the degree to which the signal intensity of the second target component signal satisfies the signal intensity constraint condition includes determining a value of the target phase difference that minimizes the discrepancy function as the target value.

In some embodiments, the determining the first target component fraction and the second target component fraction based on the target value of the target phase difference includes determining a signal intensity value of the second target component signal based on the first relational expression and the target value of the target phase difference; and determining the first target component fraction and the second target component fraction based on the signal intensity value of the second target component signal and the sum of signal intensities.

In some embodiments, the echo signal phase difference is corrected by a magnetic field inhomogeneity map.

In some embodiments, a first target component and a second target component respectively corresponding to the first target component signal and the second target component signal are different and are respectively one of water, fat, and silicone.

In some embodiments, the first echo signal is obtained based on a first MRI sequence, and the second echo signal is obtained based on a second MRI sequence. In some embodiments, the first echo signal is obtained based on a sampled signal at a first time of a third MRI sequence, and the second echo signal is obtained based on a sampled signal at a second time of the third MRI sequence.

In some embodiments, the method further includes performing a statistical calculation on the first target component fraction corresponding to the at least one echo signal pair to obtain a statistical value of the first target component fraction; and/or performing a statistical calculation on the second target component fraction corresponding to the at least one echo signal pair to obtain a statistical value of the second target component fraction.

One or more embodiments of the present disclosure provide a device or system for obtaining a component fraction for chemical shift imaging. The device or system includes at least one storage device storing an instruction set and at least one processor in communication with the at least one storage device. When the instruction set is executed, the at least one processor is configured to perform operations. The operations include obtaining one or more echo signal pairs of an object to be imaged. Each echo signal pair includes a first echo signal and a second echo signal, the first echo signal corresponds to a first echo time, the second echo signal corresponds to a second echo time, and the second echo time is different from the first echo time. The operations further include performing processing on at least one echo signal pair of the one or more echo signal pairs to obtain at least one of a first target component fraction or a second target component fraction corresponding to the at least one echo signal pair. The processing includes determining a first component phase difference based on the first echo time and a precession frequency difference between a first target component signal and a second target component signal of the at least one echo signal pair. The first component phase difference reflects a phase difference between the first target component signal and the second target component signal at the first echo time. The processing includes determining a second component phase difference based on the second echo time and the precession frequency difference. The second component phase difference reflects a phase difference between the first target component signal and the second target component signal at the second echo time. The processing further includes determining the at least one of the first target component fraction or the second target component fraction based on a signal intensity and a phase of the first echo signal, a signal intensity and a phase of the second echo signal, the first component phase difference, and the second component phase difference.

One or more embodiments of the present disclosure provide a method for obtaining a component fraction for chemical shift imaging. The method includes obtaining a first echo signal and a second echo signal of an object to be imaged. The first echo signal corresponds to a first echo time, the second echo signal corresponds to a second echo time, and the second echo time is different from the first echo time. The method includes obtaining a first signal intensity and a first phase of a first pixel point in a first echo image based on the first echo signal, and obtaining a second signal intensity and a second phase of a second pixel point in a second echo image based on the second echo signal. The method further includes determining at least one of a first target component fraction or a second target component fraction based on the first signal intensity, the first phase, the first echo time, the second signal intensity, the second phase, and the second echo time.

In some embodiments, the determining at least one of the first target component fraction or the second target component fraction based on the first signal intensity, the first phase, the first echo time, the second signal intensity, the second phase, and the second echo time includes determining an echo signal phase difference based on the first phase and the second phase, and determining at least one of the first target component fraction or the second target component fraction based on the echo signal phase difference, the first signal intensity, the first echo time, the second signal intensity, and the second echo time.

In some embodiments, the determining at least one of the first target component fraction or the second target component fraction based on the echo signal phase difference, the first signal intensity, the first echo time, the second signal intensity, and the second echo time includes determining a first component phase difference based on the first echo time and a precession frequency difference between a first target component and a second target component, wherein the first component phase difference reflects a phase difference between a first target component signal and a second target component signal at the first echo time; determining a second component phase difference based on the second echo time and the precession frequency difference, wherein the second component phase difference reflects a phase difference between the first target component signal and the second target component signal at the second echo time; and determining at least one of the first target component fraction or the second target component fraction based on the echo signal phase difference, the first signal intensity, the second signal intensity, the first component phase difference, and the second component phase difference.

In some embodiments, the determining at least one of the first target component fraction or the second target component fraction based on the echo signal phase difference, the first signal intensity, the second signal intensity, the first component phase difference, and the second component phase difference includes determining a first relational expression of a signal intensity of the second target component signal and a target phase difference based on the echo signal phase difference, the first signal intensity, the second signal intensity, the first component phase difference, and the second component phase difference, wherein the target phase difference is a phase difference between the first target component signal and the first echo signal at the first echo time; determining a signal intensity constraint condition of the first target component signal and the second target component signal based on the first signal intensity, the second signal intensity, the first component phase difference, and the second component phase difference; determining a relationship between a degree to which the signal intensity of the second target component signal satisfies the signal intensity constraint condition and the target phase difference based on the first relational expression and the signal intensity constraint condition; determining a target value of the target phase difference that maximizes the degree to which the signal intensity of the second target component signal satisfies the signal intensity constraint condition; and determining at least one of the first target component fraction or the second target component fraction based on the target value of the target phase difference.

One or more embodiments of the present disclosure provide a non-transitory computer-readable storage medium for storing computer instructions. When at least a portion of the computer instructions is executed by a processor, a method is implemented. The method includes obtaining one or more echo signal pairs of an object to be imaged. Each echo signal pair includes a first echo signal and a second echo signal, the first echo signal corresponds to a first echo time, the second echo signal corresponds to a second echo time, and the second echo time is different from the first echo time. The method further includes performing processing on at least one echo signal pair of the one or more echo signal pairs to obtain at least one of a first target component fraction or a second target component fraction corresponding to the at least one echo signal pair. The processing includes determining a first component phase difference based on the first echo time and a precession frequency difference between a first target component signal and a second target component signal of the at least one echo signal pair. The first component phase difference reflects a phase difference between the first target component signal and the second target component signal at the first echo time. The processing includes determining a second component phase difference based on the second echo time and the precession frequency difference. The second component phase difference reflects a phase difference between the first target component signal and the second target component signal at the second echo time. The processing further includes determining the at least one of the first target component fraction or the second target component fraction based on a signal intensity and a phase of the first echo signal, a signal intensity and a phase of the second echo signal, the first component phase difference, and the second component phase difference.

### BRIEF DESCRIPTION OF THE DRAWINGS

The present disclosure is further described in terms of exemplary embodiments. These exemplary embodiments are described in detail with reference to the drawings. The drawings are not to scale. These embodiments are non-limiting exemplary embodiments, in which like reference numerals represent similar structures throughout the several views of the drawings, and wherein:

FIG. 1 is a schematic diagram illustrating an exemplary component fraction acquisition system for chemical shift imaging according to some embodiments of the present disclosure;

FIG. 2 is a block diagram illustrating an exemplary component fraction acquisition system for chemical shift imaging according to some embodiments of the present disclosure;

FIG. 3 is a flowchart illustrating an exemplary process for obtaining a component fraction for chemical shift imaging according to some embodiments of the present disclosure;

FIG. 4A is a schematic diagram illustrating a first embodiment of acquiring a first echo signal and a second echo signal;

FIG. 4B is a schematic diagram illustrating a second embodiment of acquiring a first echo signal and a second echo signal;

FIG. 4C is a schematic diagram illustrating a third embodiment of acquiring a first echo signal and a second echo signal;

FIG. 5A is a schematic diagram illustrating a first echo signal according to some embodiments of the present disclosure;

FIG. 5B is a schematic diagram illustrating a second echo signal according to some embodiments of the present disclosure;

FIG. 5C is a schematic diagram illustrating an echo signal phase difference according to some embodiments of the present disclosure;

FIG. 6 is a flowchart illustrating an exemplary process for determining a first target component fraction and a second target component fraction according to some embodiments of the present disclosure;

FIG. 7 is a flowchart illustrating an exemplary process for a chemical shift imaging method according to some embodiments of the present disclosure;

FIG. 8 is a flowchart illustrating an exemplary process for obtaining a component fraction for chemical shift imaging according to some embodiments of the present disclosure;

FIG. 9A is a schematic diagram illustrating a first echo image according to some embodiments of the present disclosure;

FIG. 9B is a schematic diagram illustrating a second echo image according to some embodiments of the present disclosure;

FIG. 9C is a schematic diagram illustrating an image corresponding to a target phase difference according to some embodiments of the present disclosure;

FIG. 9D is a schematic diagram illustrating an image corresponding to a larger signal according to some embodiments of the present disclosure;

FIG. 9E is a schematic diagram illustrating an image corresponding to a smaller signal according to some embodiments of the present disclosure;

FIG. 9F is a schematic diagram illustrating an image corresponding to a sum of signal intensities according to some embodiments of the present disclosure;

FIG. 9G is a schematic diagram illustrating an image corresponding to a difference of signal intensities according to some embodiments of the present disclosure;

FIG. 9H is a schematic diagram illustrating a second target component fraction according to some embodiments of the present disclosure;

FIG. 9I is a schematic diagram illustrating a first target image according to some embodiments of the present disclosure; and

FIG. 9J is a schematic diagram illustrating a second target image according to some embodiments of the present disclosure.

### DETAILED DESCRIPTION

In the following detailed description, numerous specific details are set forth by way of examples in order to provide a thorough understanding of the relevant disclosure. However, it should be apparent to those skilled in the art that the present disclosure may be practiced without such details. In other instances, well known methods, procedures, systems, components, and/or circuitry have been described at a relatively high-level, without detail, in order to avoid unnecessarily obscuring aspects of the present disclosure. Various modifications to the disclosed embodiments will be readily apparent to those skilled in the art, and the general principles defined herein may be applied to other embodiments and applications without departing from the spirit and scope of the present disclosure. Thus, the present disclosure is not limited to the embodiments shown, but to be accorded the widest scope consistent with the claims.

It will be understood that the terms “system,” “engine,” “unit,” “module,” and/or “block” used herein are one method to distinguish different components, elements, parts, sections, or assemblies of different levels in ascending order. However, the terms may be displaced by another expression if they may achieve the same purpose.

The terminology used herein is for the purpose of describing particular example embodiments only and is not intended to be limiting. As used herein, the singular forms “a,” “an,” and “the” may be intended to include the plural forms as well, unless the context clearly indicates otherwise. It will be further understood that the terms “comprise,” “comprises,” and/or “comprising,” “include,” “includes,” and/or “including,” when used in this disclosure, specify the presence of stated features, integers, steps, operations, elements, and/or components, but do not preclude the presence or addition of one or more other features, integers, steps, operations, elements, components, and/or groups thereof.

The flowcharts used in the present disclosure illustrate operations that systems implement according to some embodiments of the present disclosure. It is to be expressly understood that the operations of the flowcharts may be implemented not in order. Conversely, the operations may be implemented in an inverted order, or simultaneously. Moreover, one or more other operations may be added to the flowcharts. One or more operations may be removed from the flowcharts.

Conventional magnetic resonance chemical shift imaging (CSI) methods are categorized into two classes. The first class involves the excitation and acquisition of signals from a single tissue component (e.g., water or fat)—such as fat saturation techniques, water excitation techniques, inversion recovery techniques, etc.—i.e., selectively suppressing or exciting the signal of one tissue component (either water or fat) to directly obtain the signal of that component. The second class involves the excitation and acquisition of signals from multiple tissue components—such as water-fat separation techniques, fat fraction (FF) quantification techniques, etc.—i.e., water and fat signals are non-selectively excited simultaneously; during data acquisition, echo signals corresponding to different acquisition parameters (typically multiple echo times) are captured, and their signal characteristics (amplitude and phase) are used to perform signal separation calculations via a mathematical model based on chemical shift (i.e., the chemical shift difference between water and fat is 3.5 ppm), thereby distinguishing between water and fat signals.

However, the aforementioned second class of methods suffers from the following two drawbacks.
1. They require the application of a regional similarity assumption or a region-growing algorithm (an image processing technique that advances signal segmentation based on the assumption of signal similarity within a local region), which may lead to water-fat signal swapping. Examples of such swapping include those caused by failures in the similarity assumption of the region-growing algorithm, improper selection of initial seeds, signal noise, complex local phase variations, etc.
2. In some scenarios, echo signals at the in-phase and out-of-phase echo times of water-fat signals may be acquired for chemical shift imaging. However, during actual echo signal acquisition, the echo signal has a certain readout length (i.e., echo signal acquisition requires a specific time duration), making it difficult to accurately align the echo time with the two time points of in-phase echo time and out-of-phase echo time. If efforts are made to precisely target these two echo times, constraints must be imposed on imaging parameters—such as using longer echo times or lower image resolution—which respectively can result in the loss of some echo signals or reduced acquired data. This, in turn compromises scan time and the resolution of reconstructed images.

In view of this, the present disclosure provides a method and system for obtaining a component fraction for chemical shift imaging. The method includes obtaining one or more echo signal pairs of an object to be imaged. Each echo signal pair includes a first echo signal and a second echo signal, the first echo signal corresponds to a first echo time, the second echo signal corresponds to a second echo time, and the second echo time is different from the first echo time. The method further includes performing processing on at least one echo signal pair of the one or more echo signal pairs to obtain at least one of a first target component fraction or a second target component fraction corresponding to the at least one echo signal pair. The processing includes determining a first component phase difference based on the first echo time and a precession frequency difference between a first target component signal and a second target component signal of the at least one echo signal pair. The first component phase difference reflects a phase difference between the first target component signal and the second target component signal at the first echo time. The processing includes determining a second component phase difference based on the second echo time and the precession frequency difference. The second component phase difference reflects a phase difference between the first target component signal and the second target component signal at the second echo time. The processing further includes determining the at least one of the first target component fraction or the second target component fraction based on a signal intensity and a phase of the first echo signal, a signal intensity and a phase of the second echo signal, the first component phase difference, and the second component phase difference.

The method enables the differentiation of different tissue components based on individual pixels of an image (i.e., pixel-wise processing). Compared with the existing second class of methods described above, it does not require the application of a regional similarity assumption for signal classification, nor does it cause water-fat signal swapping due to inherent defects of algorithms such as region growing. Additionally, the method proposed herein acquires echo signals corresponding to approximate in-phase time and approximate out-of-phase time, which reduces the requirement for echo times during signal acquisition. Thus, more data can be collected for image reconstruction, avoiding loss of image resolution.

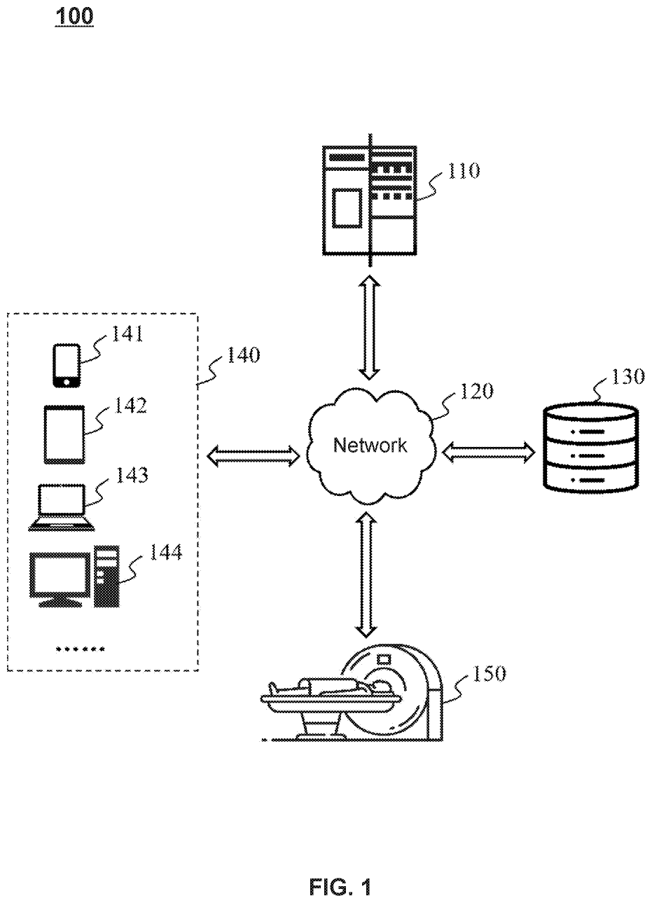

FIG. 1 is a schematic diagram illustrating an exemplary component fraction acquisition system for chemical shift imaging according to some embodiments of the present disclosure. As shown in FIG. 1, a component fraction acquisition system 100 for chemical shift imaging may include a processing device 110, a network 120, a storage device 130, a terminal device 140, and a medical imaging device 150.

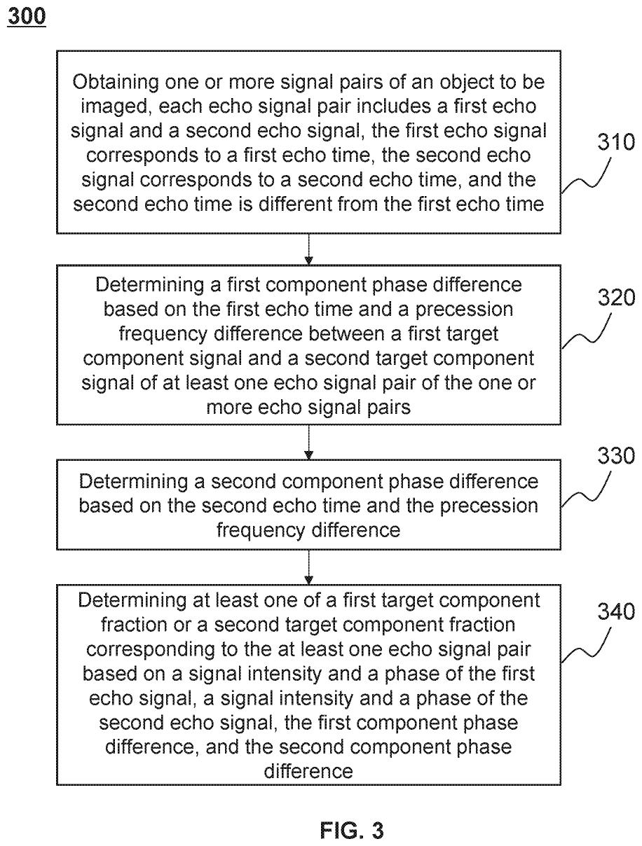

The processing device 110 is configured to process data and/or information obtained from the storage device 130, the terminal device 140, and/or the medical imaging device 150. For example, the processing device 110 obtains one or more echo signal pairs of an object to be imaged. Each echo signal pair includes a first echo signal and a second echo signal, the first echo signal corresponds to a first echo time, the second echo signal corresponds to a second echo time, and the second echo time is different from the first echo time. The processing device 110 may further perform the following processing on at least one echo signal pair of the one or more echo signal pairs to obtain at least one of a first target component fraction or a second target component fraction corresponding to the at least one echo signal pair. The processing includes determining a first component phase difference based on the first echo time and a precession frequency difference between a first target component signal and a second target component signal of the at least one echo signal pair. The first component phase difference reflects a phase difference between the first target component signal and the second target component signal at the first echo time. The processing includes determining a second component phase difference based on the second echo time and the precession frequency difference. The second component phase difference reflects a phase difference between the first target component signal and the second target component signal at the second echo time. The processing further includes determining the at least one of the first target component fraction or the second target component fraction based on a signal intensity and a phase of the first echo signal, a signal intensity and a phase of the second echo signal, the first component phase difference, and the second component phase difference. More details about the above examples may be found in FIG. 3 and its related description.

In some embodiments, the processing device 110 may include a processor. In some embodiments, the processing device 110 may be a single server or a server group.

The network 120 may be configured to connect the various components of the component fraction acquisition system 100 and/or connect the component fraction acquisition system 100 with an external resource. The network 120 enables communication between the various components of the component fraction acquisition system 100 and/or communication between the component fraction acquisition system 100 and the external resource, thereby facilitating the exchange of data and/or information. For example, the network 120 may transmit the first echo signal and/or the second echo signal of the object to be imaged obtained by the medical imaging device 150 to the processing device 110. As another example, the network 120 may transmit instructions input by a user through the terminal device 140 (for example, instructions for controlling the medical imaging device 150 to image the object to be imaged) to the medical imaging device 150.

The storage device 130 may be configured to store data and/or instructions. For example, the storage device 130 may be configured to store the first echo signal and/or the second echo signal of the object to be imaged obtained by the medical imaging device 150, the first target component fraction and the second target component fraction determined by the processing device 110, etc. The storage device 130 may be implemented in a single central server, a plurality of servers, or a plurality of personal devices connected via communication links.

The terminal device 140 refers to one or more terminal devices or software used by a user. The user refers to an operator of the medical imaging device 150, for example, a doctor, an experimenter, or the like. In some embodiments, the terminal device 140 may be a device that has input and/or output functions, such as a mobile device 141, a tablet computer 142, a laptop computer 143, a desktop computer 144, or the like, or any combination thereof.

The medical imaging device 150 is a device configured to image the object to be imaged (for example, a patient, an experimental subject, or the like). For example, the medical imaging device 150 may be a Magnetic Resonance Imaging (MRI) device, a Nuclear Magnetic Resonance Imaging (NMRI) device, or the like.

It should be noted that the component fraction acquisition system 100 is provided merely for illustrative purposes and is not intended to limit the scope of the present disclosure. For a person of ordinary skill in the art, modifications or variations may be made based on the description of the present disclosure. For example, the terminal device 140 may also include other types of terminals. However, these variations and modifications do not depart from the scope of the present disclosure.

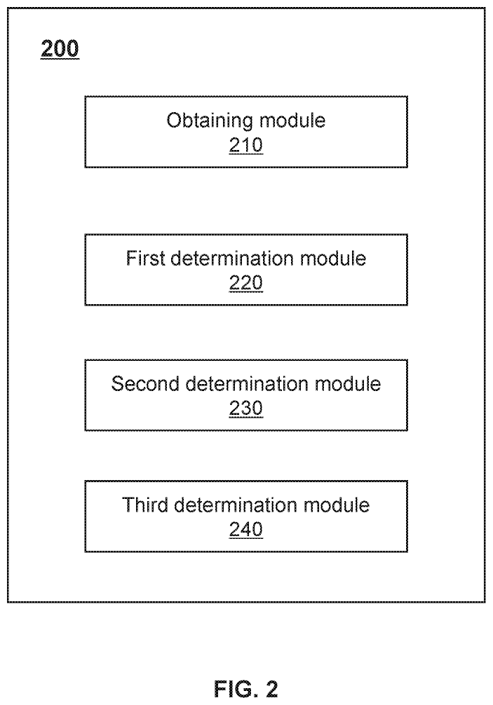

FIG. 2 is a block diagram illustrating an exemplary component fraction acquisition system for chemical shift imaging according to some embodiments of the present disclosure. In some embodiments, as shown in FIG. 2, the component fraction acquisition system 200 for chemical shift imaging may include an obtaining module 210, a first determination module 220, a second determination module 230, and a third determination module 240.

The obtaining module 210 is configured to obtain one or more signal pairs of an object to be imaged. Each echo signal pair includes a first echo signal and a second echo signal, the first echo signal corresponds to a first echo time, the second echo signal corresponds to a second echo time, and the second echo time is different from the first echo time.

The first determination module 220 is configured to determine a first component phase difference based on the first echo time and a precession frequency difference between a first target component signal and a second target component signal of at least one echo signal pair of the one or more echo signal pairs. The first component phase difference reflects a phase difference between the first target component signal and the second target component signal at the first echo time.

The second determination module 230 is configured to determine a second component phase difference based on the second echo time and the precession frequency difference. The second component phase difference reflects a phase difference between the first target component signal and the second target component signal at the second echo time.

The third determination module 240 is configured to determine the at least one of the first target component fraction or the second target component fraction corresponding to the at least one echo signal pair based on a signal intensity and a phase of the first echo signal, a signal intensity and a phase of the second echo signal, the first component phase difference, and the second component phase difference.

More description regarding the obtaining module 210, the first determination module 220, the second determination module 230, and the third determination module 240 may be referred to in FIG. 3 and the related description thereof.

It should be noted that the above description of the component fraction acquisition system 200 and the modules thereof is merely provided for the purposes of illustration, and does not limit the present disclosure to the scope of the illustrated embodiments. It can be understood that, for those skilled in the art, after understanding the principle of the system, they may, without departing from this principle, arbitrarily combine the various modules, or form a subsystem connected to the other modules. In some embodiments, the obtaining module 210, the first determination module 220, the second determination module 230, and the third determination module 240 disclosed in FIG. 2 may be different modules in a system, or any two or more of the obtaining module 210, the first determination module 220, the second determination module 230, and the third determination module 240 may be combined to as a single module that may implement the functions of two or more of the above-mentioned modules. In some embodiments, the obtaining module 210, the first determination module 220, the second determination module 230, and the third determination module 240 may share a storage module, or each module may have a respective storage module. Such variations are all within the scope of the present disclosure.

FIG. 3 is a flowchart illustrating an exemplary process for obtaining a component fraction for chemical shift imaging according to some embodiments of the present disclosure. As shown in FIG. 3, a process 300 includes the following steps. In some embodiments, the process 300 may be executed by a processing device (e.g., the processing device 110) or the component fraction acquisition system 200.

Step 310, obtaining one or more signal pairs of an object to be imaged. In some embodiments, step 310 may be executed by the processing device (e.g., the processing device 110) or the obtaining module 210.

In some embodiments, each echo signal pair includes a first echo signal and a second echo signal.

The object to be imaged refers to an object imaged by a medical imaging device (e.g., the medical imaging device 150). For example, the object to be imaged may be a patient, an experimental subject, or the like, imaged by the medical imaging device, or at least one part (e.g., a chest, an abdomen, limbs, or the like) or organ (e.g., a heart, a liver, lungs, or the like) of the patient, the experimental subject, or the like.

An echo signal refers to a signal generated by relaxation of magnetization vectors of protons in the tissue of the object to be imaged, which is detected during the imaging process of the medical imaging device (e.g., the medical imaging device 150) after emitting the radio frequency (RF) pulse.

An echo time may refer to a time interval from an end time point of the radio frequency pulse to a time point when the medical imaging device detects a maximum amplitude of the echo signal (i.e., a peak of the echo signal).

In magnetic resonance imaging (MRI), an MRI sequence is a timing combination designed to generate echo signals (or echo images), including a series of radio frequency pulse emissions, gradient magnetic field emissions, and signal acquisitions. A radio frequency pulse is a radio wave of a specific frequency, whose frequency range is usually in the MHz band (e.g., about 64 MHz at a 1.5 T field strength). During the magnetic resonance imaging process, the radio frequency pulse of the certain frequency is usually applied on the basis of a main magnetic field, so that a magnetization vector deflects positively relative to a z-axis, such as a 90° or 180° deflection. At this time, the magnetization vector generates components in an xy plane, and the xy components of the magnetization vector are acquired by a coil whose central axis is parallel to a direction (the z-axis) of the main magnetic field. The components of the magnetization vector in the xy plane generate an induced signal in the coil, which is an MRI signal. A gradient magnetic field is a magnetic field superimposed on the main magnetic field, whose intensity linearly changes with space. The gradient magnetic field may be a linearly changing magnetic field generated by electromagnetic coils in three directions (x, y, z). A gradient magnetic field is used for spatial encoding (including imaging slice selection (e.g., selecting a slice of voxels along a z-axis direction of the human body for imaging), frequency encoding, and phase encoding) and for locating a signal source. Signal acquisition is a process of receiving echo signals emitted during a relaxation process of hydrogen protons within a specific time window in the MRI sequence. The echo time in some embodiments of the present disclosure may be a signal acquisition time in the MRI sequence. Types of MRI sequences include spin echo sequences, inversion recovery sequences, gradient echo (GRE) sequences, Propeller/Blade sequences, Echo Planar Imaging (EPI) sequences, Principle of Echo-shifting with a Train of Observations (PRESTO) sequences, Gradient and Spin Echo (GRASE) sequences, and the like. In different types of MRI sequences, a timing of signal acquisition may be different. By way of example, taking a medical imaging device as a magnetic resonance imaging device as an example, during a magnetic resonance imaging process, after emitting an initial radio frequency pulse, a relaxation of magnetization vectors of protons in a tissue generates a signal. The signal is detected after a certain time by a signal receiving component (e.g., a receiving coil) of the medical imaging device. The detected signal refers to an echo signal, and the ‘certain time’ may be considered as an echo time. After detecting the echo signal, the signal receiving component may convert the echo signal into an electrical signal.

It can be understood that the medical imaging device, during the imaging process, after emitting the RF pulse, the signal receiving component may detect at least one (typically a plurality of) echo signals, wherein each echo signal corresponds to the respective echo time. After the medical imaging device detects a plurality of echo signals, two echo signals may be arbitrarily selected (e.g., randomly selected) therefrom as the first echo signal and the second echo signal, respectively, wherein the first echo signal corresponds to the first echo time (e.g., the first echo signal is an echo signal detected by the medical imaging device after emitting the initial radio frequency pulse and after the first echo time), and the second echo signal corresponds to the second echo time (e.g., the second echo signal is an echo signal detected by the medical imaging device after emitting the initial radio frequency pulse and after the second echo time). The second echo time is different from the first echo time (based on this, the first echo signal and the second echo signal are different echo signals).

In some embodiments, the first echo signal is obtained based on a first MRI sequence, and the second echo signal is obtained based on a second MRI sequence; or, the first echo signal is obtained based on a sampled signal at a first time of a third MRI sequence, and the second echo signal is obtained based on a sampled signal at a second time of the third MRI sequence. A first time and the second time respectively refer to signal acquisition times in the corresponding MRI sequence when the first echo signal and the second echo signal are acquired. The sampled signal at the first time is an electrical signal obtained at one of two or more signal acquisition times in the third MRI sequence. The sampled signal at the second time is an electrical signal obtained at another one of the two or more signal acquisition times in the third MRI sequence.

In some embodiments, the first MRI sequence is a certain MRI sequence selected from a plurality of MRI sequences, and the second MRI sequence is another MRI sequence selected from the plurality of MRI sequences, wherein the first MRI sequence is different from the second MRI sequence. The third MRI sequence is a certain MRI sequence selected from the plurality of MRI sequences, which may be the same as or different from the first MRI sequence and the second MRI sequence. The third MRI sequence needs to have two or more signal acquisition times (an MRI sequence may be considered as a time period, and the third MRI sequence is designed with two or more signal acquisition time points so as to realize signal acquisition at two or more different time points in the MRI sequence period).

In some embodiments, the first echo time is closer to an in-phase echo time than the second echo time, which may also be understood as meaning that the first echo time is farther from an opposed-phase echo time than the second echo time. The second echo time may be closer to the opposed-phase echo time than the first echo time, which may also be understood as meaning that the second echo time is farther from the in-phase echo time than the first echo time.

In some embodiments, the in-phase echo time may be an in-phase echo time of a first target component signal and a second target component signal. Specifically, the in-phase echo time may be a time at which a phase difference between the first target component signal and the second target component signal in the echo signal is 2nπ (where n is an integer).

The first target component signal may refer to a portion of the signal generated by the first target component of the object to be imaged within the echo signal, and the second target component signal may refer to a portion of the signal generated by the second target component of the object to be imaged within the echo signal. In some embodiments, the process shown in FIG. 3 is applicable to the processing of each pixel of an image. Accordingly, the first target component signal may be regarded as a portion generated by the first target component in the echo signal corresponding to each pixel of a reconstructed image (for example, a first echo image or a second echo image). The second target component signal refers to a portion generated by the second target component in the echo signal corresponding to each pixel of the reconstructed image. More description of the first echo image and the second echo image may be found in the related description hereinafter.

The first target component and the second target component refer to tissue components in the tissue of the object to be imaged for which the component fraction is to be determined.

In some embodiments, the first target component may be different from the second target component, and each may be one of the following materials: water, fat, and silicone. For example, the first target component is water, and the second target component is fat.

The component fraction refers to a proportion of the signal generated by the different tissue components (for example, the first target component and the second target component) in the echo signal corresponding to each pixel of the reconstructed image (for example, the first echo image or the second echo image). For example, the component fraction of the first target component (referred to as a first target component fraction) may be a proportion of the first target component signal in the echo signal corresponding to each pixel of the reconstructed image, for example, a proportion of the signal generated by water; and the component fraction of the second target component (referred to as a second target component fraction) may be a proportion of the second target component signal in the echo signal corresponding to each pixel of the reconstructed image, for example, a proportion of the signal generated by fat.

In some embodiments, the in-phase echo time may be determined based on the following Formula (1):

$${TE}_{ip} = \frac{n}{Δ ω} , \qquad ( 1 )$$

where TEᵢₚ is the in-phase echo time; Δω is a precession frequency difference between the first target component and the second target component. For example, taking the first target component as water and the second target component as fat as an example, the precession frequency difference between the two is 3.5 ppm, and the precession frequency difference Δω between a water signal and a fat signal is 420 Hz in a main magnetic field with a magnetic field strength of 3 T. n is an integer.

The precession frequency refers to a frequency at which a spin magnetic moment of a magnetic atomic nucleus (for example, a hydrogen nucleus) rotates, in an external magnetic field, around a direction of the external magnetic field.

The precession frequency may be determined based on the following Formula (2):

ω=γ×B₀ (2),

where ω is the precession frequency; γ is a gyromagnetic ratio (a constant), a value of γ is only related to an atomic nucleus type; and B₀ is a magnetic field strength of the external magnetic field.

It can be understood that the value of γ is only related to the atomic nucleus type. Therefore, when the first target component and the second target component are determined (for example, the first target component is water, and the second target component is fat), their atomic types are also determined accordingly. In the case where the same B₀ is applied, the precession frequencies of the first target component and the second target component are fixed values. Based on this, the precession frequency difference between the first target component and the second target component is a fixed value.

The opposed-phase echo time is an opposed-phase echo time of the first target component signal and the second target component signal. Further, the opposed-phase echo time refers to an echo time that causes a phase difference between the first target component signal and the second target component signal in the echo signal to be (2n+1)π (where n is an integer).

In some embodiments, the opposed-phase echo time may be determined based on the following Formula (3):

$${TE}_{op} = \frac{n + 0.5}{Δ ω} \qquad ( 3 )$$

where TEₒₚ is the opposed-phase echo time, and the meanings of other parameters are the same as those in Formula (1).

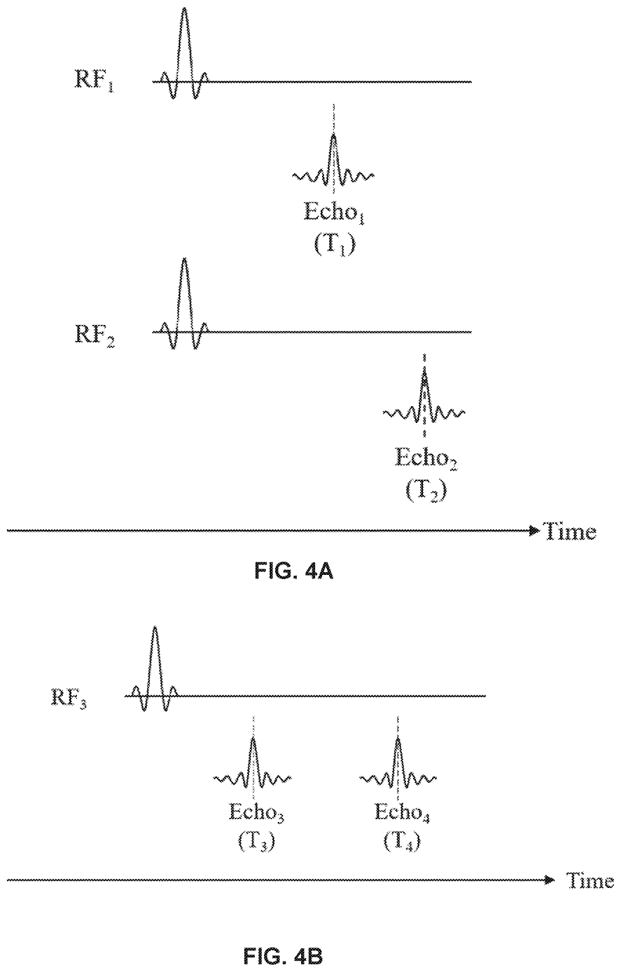

FIG. 4A is a schematic diagram illustrating a first embodiment of acquiring a first echo signal and a second echo signal; FIG. 4B is a schematic diagram illustrating a second embodiment of acquiring a first echo signal and a second echo signal; and FIG. 4C is a schematic diagram illustrating a third embodiment of acquiring a first echo signal and a second echo signal.

It should be noted that a medical imaging device (for example, the medical imaging device 150) may release one or more RF pulses during an imaging process. The first echo signal and the second echo signal may be selected from different echo signals corresponding to the same RF pulse, or may be selected from echo signals corresponding to different RF pulses.

Exemplarily, as shown in FIG. 4A, the RF pulses released by the medical imaging device include RF₁ and RF₂, and two echo signals selected from a plurality of detected echo signals include Echo₁ and Echo₂, wherein Echo₁ is an echo signal detected after RF₁ is released, Echo₂ is an echo signal detected after RF₂ is released; the echo time corresponding to Echo₁ is T₁, and the echo time corresponding to Echo₂ is T₂. T₁ and T₂ have different positions on a time axis (the time axis in FIG. 4A). Therefore, T₁ and T₂ are different echo times.

Further, if T₁ is closer to the in-phase echo time relative to T₂, then Echo₁ is used as the first echo signal, and Echo₂ is used as the second echo signal; if T₁ is closer to the opposed-phase echo time relative to T₂, then Echo₁ is used as the second echo signal, and Echo₂ is used as the first echo signal.

As another example, as shown in FIG. 4B, the RF pulse released by the medical imaging device includes RF₃, and two echo signals selected from a plurality of detected echo signals include Echo₃ and Echo₄, wherein the echo time corresponding to Echo₃ is T₃, and the echo time corresponding to Echo₄ is T₄. T₃ and T₄ have different positions on a time axis (the time axis in FIG. 4B). Therefore, T₃ and T₄ are different echo times.

Further, if T₃ is closer to the in-phase echo time relative to T₄, then Echo₃ is used as the first echo signal, and Echo₄ is used as the second echo signal; if T₃ is closer to the opposed-phase echo time relative to T₄, then Echo₃ is used as the second echo signal, and Echo₄ is used as the first echo signal.

As another example, as shown in FIG. 4C, the RF pulses released by the medical imaging device include RF₄ and RF₅, and four echo signals selected from a plurality of detected echo signals include Echo₅, Echo₆, Echo₇, and Echo₈, wherein Echo₅ and Echo₆ are the echo signals detected after RF₄ is released, Echo₇ and Echo₈ are the echo signals detected after RF₅ is released; the echo time corresponding to Echo₅ is T₅, the echo time corresponding to Echo₆ is T₆, the echo time corresponding to Echo₇ is T₇, and the echo time corresponding to Echo₈ is T₈. T₅, T₆, T₇, and T₈ have different positions on a time axis (the time axis in FIG. 4C). Therefore, T₅, T₆, T₇, and T₈ are different echo times.

Further, two may be selected from the above four echo signals to be used respectively as the first echo signal and the second echo signal. For example, assuming that Echo₅ and Echo₆ are selected, if T₅ is closer to the in-phase echo time relative to T₆, then Echo₅ is used as the first echo signal, and Echo₆ is used as the second echo signal; if T₅ is closer to the opposed-phase echo time relative to T₆, then Echo₅ is used as the second echo signal, and Echo₆ is used as the first echo signal. As another example, assuming that Echo₆ and Echo₈ are selected, if T₆ is closer to the in-phase echo time relative to T₈, then Echo₆ is used as the first echo signal, and Echo₈ is used as the second echo signal; if T₆ is closer to the opposed-phase echo time relative to T₈, then Echo₆ is used as the second echo signal, and Echo₈ is used as the first echo signal.

In some embodiments, the first echo image and the second echo image may be determined respectively based on the first echo signal and the second echo signal.

In some embodiments, the medical imaging device (for example, the medical imaging device 150) or the processing device (for example, the processing device 110) may perform reconstruction based on the echo signal to obtain a reconstructed image (for example, a magnetic resonance image). Exemplarily, the signal receiving component (for example, a receiving coil) of the medical imaging device may convert the echo signal into electrical signals; the processing device may digitize the electrical signals; the digitized echo signals are represented as a series of complex data in K-space, and the processing device may perform appropriate signal processing (for example, Fourier transform) on the digitized echo signals to obtain the reconstructed image.

Taking the first echo signal as an example, the first echo signal may be obtained through the operations shown in the following process.
1. Performing a plurality of MRI scans (such as 256 times, 128 times, or the like) on the object to be imaged, wherein each scan corresponds to a first MRI sequence, that is, repeatedly performing the first MRI sequence a plurality of times.
2. Each time the first MRI sequence is completed, the signal receiving component (for example, the receiving coil) of the medical imaging device obtains electrical signals generated in response to the echo signals emitted by the object to be imaged at the signal acquisition time of the first MRI sequence.
3. The processing device digitizes the electrical signals and fills K-space using the digitized data; each scan fills a portion of K-space, therefore, a plurality of scans are needed until K-space is filled.
4. The processing device performs appropriate signal processing (for example, a Fourier transform) on the data of K-space to obtain the reconstructed image (that is, the first echo signal or the first echo image).

The reconstructed image may be regarded as a two-dimensional matrix composed of complex numbers, wherein each matrix element corresponds to a pixel or a voxel, a modulus value of a complex number is an intensity value of the first echo signal of the pixel, and an angle of the complex number is a phase value of the first echo signal of the pixel.

Similarly, the second echo signal is obtained based on a second MRI sequence, and the steps for obtaining the second echo signal may be similar to the above-described steps for obtaining the first echo signal, and details are not repeated here.

Based on this, in some embodiments, the medical imaging device or the processing device (for example, the processing device 110) may reconstruct the first echo image based on the first echo signal, and reconstruct the second echo image based on the second echo signal. It can be understood that the first echo image and the second echo image are both reconstructed images.

The first echo image and the second echo image both include a plurality of pixels. For convenience of description, the pixels of the first echo image may be referred to as first pixels, and the pixels of the second echo image may be referred to as second pixels. Pixel values of the first pixels may reflect a distribution of the first echo signal in a spatial domain, and the pixel values of the first pixels may specifically include amplitude information and phase information of the corresponding first echo signal. Pixel values of the second pixels may reflect a distribution of the second echo signal in a spatial domain, and the pixel values of the second pixels may specifically include amplitude information and phase information of the corresponding second echo signal. It should be understood that the steps involved hereinafter are also applicable to pixel-level processing of the reconstructed image, unless otherwise specified. For example, the first echo signal and the second echo signal in the steps involved hereinafter may be respectively regarded as an echo signal corresponding to a first pixel in the first echo image and an echo signal corresponding to a second pixel corresponding to the first pixel in the second echo image. The aforementioned correspondence between the pixels may be understood as a position of the first pixel in the first echo image being the same as a position of the second pixel in the second echo image, for example, having the same position coordinates in the images.

In some embodiments, the processing device may perform the following steps 320-340 on at least one echo signal pair of one or more echo signal pairs to obtain at least one of a first target component fraction and a second target component fraction corresponding to the at least one echo signal pair. Each echo signal pair includes a first echo signal and a second echo signal, the first echo signal corresponds to a first echo time, the second echo signal corresponds to a second echo time, and the second echo time is different from the first echo time. The echo signal pairs may be obtained by selecting a plurality of echo signals and pairing them in two, for example, assuming there are echo signal 1, echo signal 2, and echo signal 3, the first echo signal pair (echo signal 1 and echo signal 2) and the second echo signal pair (echo signal 2 and echo signal 3) can be formed. A count of echo signals may be either or odd.

Step 320, determining a first component phase difference based on the first echo time and the precession frequency difference between the first target component and the second target component corresponding to the at least one echo signal pair. In some embodiments, step 320 may be performed by the processing device (for example, the processing device 110) or the first determination module 220.

The first component phase difference reflects a phase difference between the first target component signal and the second target component signal at the first echo time.

In some embodiments, a vector expression corresponding to a signal may be constructed based on a signal intensity and a phase of the signal.

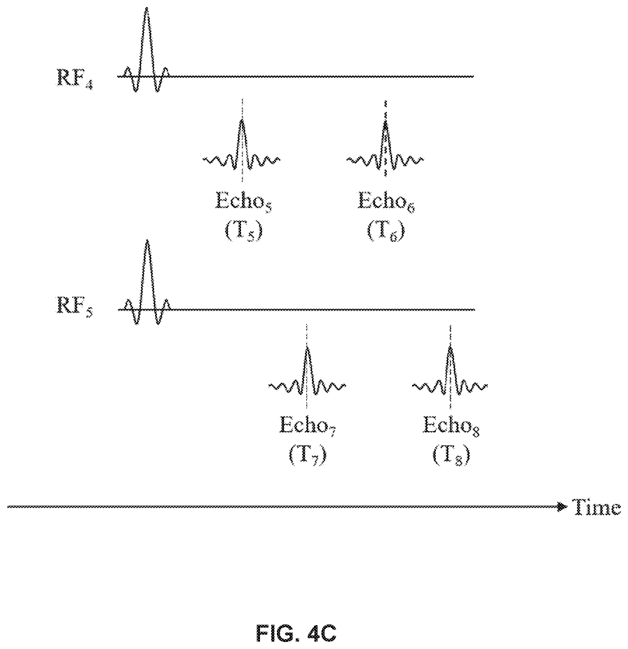

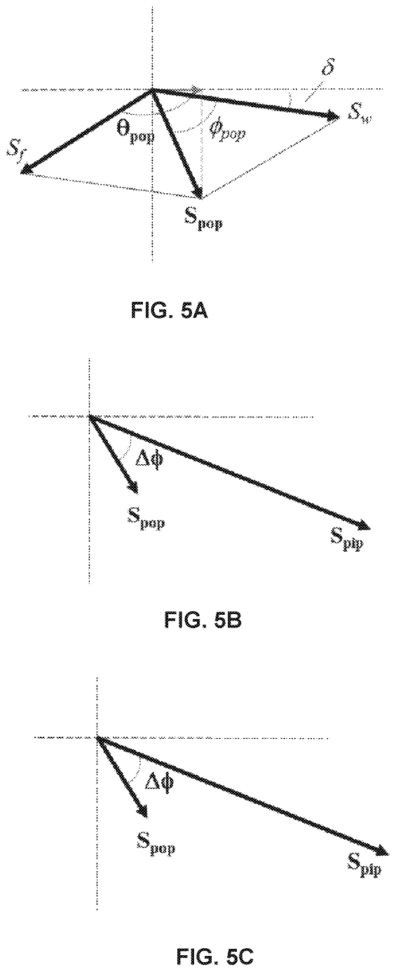

FIG. 5A is a schematic diagram illustrating a first echo signal according to some embodiments of the present disclosure.

As shown in FIG. 5A, in a complex plane, a vector Sₚᵢₚ represents the first echo signal. Specifically, a modulus (length) of the Sₚᵢₚ characterizes a signal intensity of the first echo signal, and a direction of the Sₚᵢₚ characterizes a phase of the first echo signal. Furthermore, the Sₚᵢₚ may be regarded as a vector sum of vectors S_{w} and S_{f}, wherein the S_{w} represents a first target component signal. Specifically, a modulus of the S_{w} characterizes a signal intensity of the first target component signal, and a direction of the S_{w} characterizes a phase of the first target component signal. The S_{f} represents a second target component signal. Specifically, a modulus of the S_{f} characterizes a signal intensity of the second target component signal, and a direction of the S_{f} characterizes a phase of the second target component signal. Based on this, the first component phase difference (represented by θₚᵢₚ) is a phase difference between the S_{w} and the S_{f} (characterized by an angle between the S_{w} and the S_{f}).

Furthermore, as shown in FIG. 5A, the Φₚᵢₚ is the angle between the Sₚᵢₚ and the S_{w}, which may characterize the phase difference between the first echo signal and the first target component signal. An angle δ between the S_{w} and a zero-phase direction is a baseline phase, which represents a phase difference between the S_{w} and a zero phase (with a phase value of 0). In some embodiments, a value of the baseline phase δ is related to a hardware configuration (for example, a model of the medical imaging device) and a readout manner, etc.

In some embodiments, based on the vectors shown in FIG. 5A, the following relational expression (4) may be obtained:

Sₚᵢₚ·cos(Φₚᵢₚ+δ)=S_{w}·cos(δ)+S_{f}·cos(θₚᵢₚ+δ) (4),

where the meanings of the various parameters may be referred to in the foregoing description.

In some embodiments, the first component phase difference may be determined based on the following Formula (5):

θₚᵢₚ=Δω·TEₚᵢₚ (5),

where the θₚᵢₚ is the first component phase difference; the TEₚᵢₚ is the first echo time, and the meanings of the other parameters are the same as those in Formula (1).

Step 330, determining a second component phase difference based on the second echo time and the precession frequency difference. In some embodiments, step 330 may be performed by the processing device (for example, the processing device 110) or the second determination module 230.

The second component phase difference reflects a phase difference between the first target component signal and the second target component signal at the second echo time.

FIG. 5B is a schematic diagram illustrating a second echo signal according to some embodiments of the present disclosure.

As shown in FIG. 5B, a vector Sₚₒₚ represents the second echo signal. Specifically, a modulus of the Sₚₒₚ characterizes a signal intensity of the second echo signal, and a direction of the Sₚₒₚ characterizes a phase of the second echo signal. Furthermore, the Sₚₒₚ may be regarded as a vector sum of vectors S_{w} and S_{f}. The S_{w} represents the first target component signal, and the S_{f} represents the second target component signal. Based on this, the second component phase difference (represented by θₚₒₚ) is a phase difference between the S_{w} and the S_{f} (characterized by an angle between the S_{w} and the S_{f}).

Furthermore, as shown in FIG. 5B, the Φₚₒₚ is the angle between the Sₚₒₚ and the S_{w}, which may characterize a phase difference between the second echo signal and the first target component signal. The δ is the baseline phase.

In some embodiments, based on the vectors shown in FIG. 5B, the following relational expression (6) may be obtained:

Sₚₒₚ·cos(Φₚₒₚ+δ)=S_{w}·cos(δ)+S_{f}·cos(θₚₒₚ+δ) (6),

where the meanings of the various parameters may be referred to in the foregoing description.

In some embodiments, the second component phase difference may be determined based on the following Formula (7):

θₚₒₚ=Δω·TEₚₒₚ (7),

where the θₚₒₚ is the second component phase difference; the TEₚₒₚ is the second echo time, and the meanings of the other parameters are the same as those in Formula (3).

Step 340, determining at least one of a first target component fraction and a second target component fraction corresponding to the at least one echo signal pair based on a signal intensity and a phase of the first echo signal, a signal intensity and a phase of the second echo signal, the first component phase difference, and the second component phase difference. In some embodiments, step 340 may be performed by the processing device (for example, the processing device 110) or the third determination module 240.

In conjunction with the foregoing description, the first target component fraction refers to a proportion, in an echo signal (for example, the first echo signal or the second echo signal), of a signal generated by the first target component in a tissue. For example, it refers to a proportion of a signal generated by water in the tissue. The second target component fraction refers to a proportion, in an original echo signal, of a signal generated by the second target component in a tissue. For example, it refers to a proportion of a signal generated by fat in the tissue.

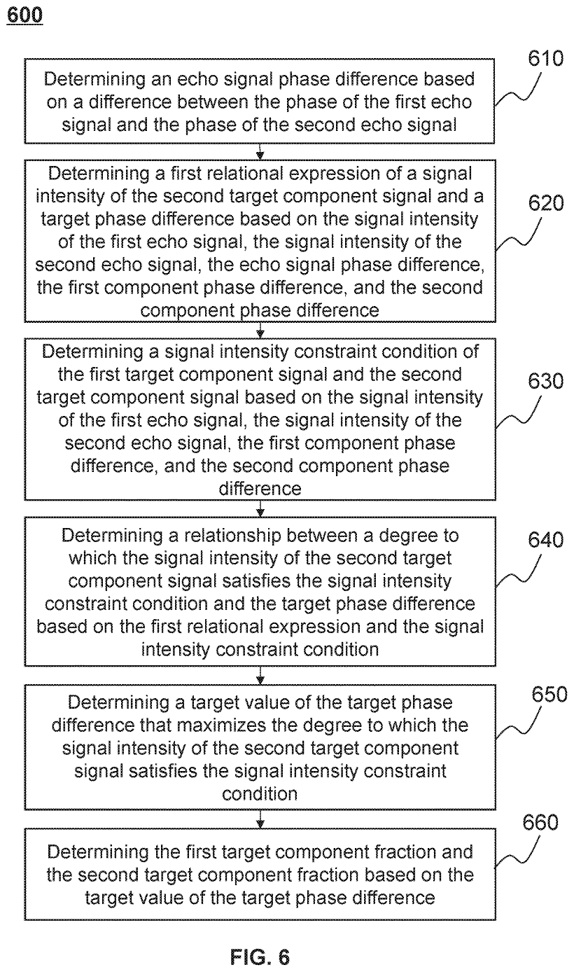

In some embodiments, the processing device (e.g., the processing device 110) or the third determination module 240 may determine an echo signal phase difference based on a difference between the phase of the first echo signal and the phase of the second echo signal; determine a first relational expression of a signal intensity of the second target component signal and a target phase difference based on the signal intensity of the first echo signal, the signal intensity of the second echo signal, the echo signal phase difference, the first component phase difference, and the second component phase difference, wherein the target phase difference is a phase difference between the first target component signal and the first echo signal at the first echo time; determine a signal intensity constraint condition of the first target component signal and the second target component signal based on the signal intensity of the first echo signal, the signal intensity of the second echo signal, the first component phase difference, and the second component phase difference; determine a relationship between a degree to which the signal intensity of the second target component signal satisfies the signal intensity constraint condition and the target phase difference based on the first relational expression and the signal intensity constraint condition; determine a target value of the target phase difference that maximizes the degree to which the signal intensity of the second target component signal satisfies the signal intensity constraint condition; and determine the first target component fraction and the second target component fraction based on the target value of the target phase difference. More description of the above-described embodiments may be found in FIG. 6 and the related description thereof.

In some embodiments, the process 300 shown in FIG. 3 may be performed on a first pixel point in the first echo image and a second pixel point corresponding to the first pixel point in the second echo image. After traversing each of the first pixel points in the first echo image and the corresponding second pixel points in the second echo image, the first target component fraction and the second target component fraction for each of the pixel points may be obtained.

In some embodiments, the processing device may perform a statistical calculation on the first target component fraction corresponding to the at least one echo signal pair to obtain a statistical value of the first target component fraction; and/or perform a statistical calculation on the second target component fraction corresponding to the at least one echo signal pair to obtain a statistical value of the second target component fraction. Since the foregoing steps are performed based on selecting two echo signals from the plurality of acquired echo signals as the first echo signal and the second echo signal, respectively, for processing, it can be understood that the other echo signals in the plurality of acquired echo signals, besides the two echo signals, are not utilized. Accordingly, in some embodiments, a plurality of calculation rounds may be performed. In each calculation round, two echo signals may be selected from the plurality of echo signals as a group of echo signals (or referred to as an echo signal pair). The two echo signals in the group of echo signals may be used as the first echo signal and the second echo signal, respectively, to perform the calculation process shown in FIG. 3, so as to obtain a calculation result until all possible echo signal combinations have been calculated. After the above-described plurality of calculation rounds, each pixel point pair may correspond to a plurality of first target component fractions and a plurality of second target component fractions. Further, the calculation results obtained from the plurality of calculation rounds may undergo comprehensive processing, and the comprehensive processing result may be used as the final calculation result. For example, the plurality of first target component fractions corresponding to each pixel point may be statistically calculated (e.g., by taking an average or a median) to obtain a final first target component fraction (i.e., the statistical value of the first target component fraction) for each pixel point. The plurality of second target component fractions corresponding to each pixel point may be statistically calculated (e.g., by taking an average or a median) to obtain a final second target component fraction (i.e., the statistical value of the second target component fraction) for each pixel point. In the embodiments of the present disclosure, determining the first target component fraction and the second target component fraction through the manner of the above-described plurality of calculation rounds can enable the plurality of acquired echo signals to be fully utilized, avoid an accidental deviation of the calculation results caused by only using a portion of the echo signals, and improve the accuracy and adaptability of the determined first target component fraction and the second target component fraction.

In some embodiments of the present disclosure, obtaining echo signals at different times as approximate in-phase echo signals (e.g., the first echo signal) and approximate opposed-phase echo signals (e.g., the second echo signal) for calculation processing, without obtaining accurate in-phase echo signals and opposed-phase echo signals, reduces the requirement for sampling time and avoids loss of sampled data amount and image resolution. The calculation process of the first target component fraction and the second target component fraction may be implemented pixel-by-pixel, without applying a regional similarity assumption for signal classification, and does not produce water-fat signal swapping phenomena caused by defects of the algorithm itself, such as regional growth. The calculated target component fractions may be applied in chemical shift imaging for a variety of scenarios, such as improving image contrast and clarity, lesion detection and assessment, and accurate information extraction.

It should be noted that the above-described description of the process 300 is merely for illustration and explanation, and does not limit the scope of applicability of the present disclosure. For a person skilled in the art, various modifications and alterations may be made to the process 300 under the guidance of the present disclosure. However, the modifications and alterations are still within the scope of the present disclosure.

FIG. 6 is a flowchart illustrating an exemplary process for determining a first target component fraction and a second target component fraction according to some embodiments of the present disclosure. As shown in FIG. 6, a process 600 includes the following steps. In some embodiments, the process 600 may be performed by the processing device (for example, the processing device 110) or the third determination module 240.

Step 610, determining an echo signal phase difference based on a difference between the phase of the first echo signal and the phase of the second echo signal.

The echo signal phase difference may be a difference between the phase of the first echo signal and the phase of the second echo signal.

FIG. 5C is a schematic diagram illustrating an echo signal phase difference according to some embodiments of the present disclosure.

In conjunction with FIG. 5A and FIG. 5B, as shown in FIG. 5C, a vector Sₚᵢₚ represents the first echo signal, a direction of Sₚᵢₚ characterizes the phase of the first echo signal, a vector Sₚₒₚ represents the second echo signal, and a direction of Sₚₒₚ characterizes the phase of the second echo signal. Accordingly, an angle between the vector Sₚᵢₚ and the vector Sₚₒₚ (represented by ΔΦ) may represent the echo signal phase difference.

In some embodiments, based on the vectors shown in FIG. 5C, the following relational expression (8) may be obtained:

ΔΦ=Φₚₒₚ−Φₚᵢₚ (8),

where the meaning of the various parameters may refer to FIG. 3 and related descriptions thereof.

In some embodiments, the echo signal phase difference may be corrected by a magnetic field inhomogeneity map. Specifically, the echo signal phase difference (which may be regarded as a two-dimensional image of the same size as the first echo image or the second echo image, wherein each element is a phase difference value between the first echo signal and the second echo signal for a corresponding pixel or voxel point) and the magnetic field inhomogeneity map (which may be regarded as a two-dimensional image of the same size as the first echo image or the second echo image, wherein each element is a main magnetic field strength value for a space in which the corresponding pixel or voxel point located) may be used as input data of a correction algorithm. After processing by the correction algorithm, a corrected echo signal phase difference image is obtained.

The echo signal phase difference may include an additional phase value due to the magnetic field inhomogeneity of a medical imaging device (for example, the medical imaging device 150). Based on this, in some embodiments, the inhomogeneity map (also referred to as the magnetic field inhomogeneity map) of the main magnetic field B0 of the medical imaging device may be determined to correct the echo signal phase difference, so as to eliminate or reduce the additional phase value, thereby obtaining an accurate value of the echo signal phase difference. It can be understood that the additional phase value included in the echo signal phase difference may be regarded as an error of the echo signal phase difference, which may affect the calculation accuracy of subsequent steps.

A voxel point in the magnetic field inhomogeneity map may characterize a difference between an actual magnetic field strength (mainly referring to the main magnetic field B0) and a nominal magnetic field value at a spatial position where the voxel point is located. The nominal magnetic field value may be a magnetic field strength of the main magnetic field B0 desired or set by a user. For example, the nominal magnetic field value may be a static magnetic field with a magnetic induction intensity of 3 T.

The magnetic field inhomogeneity map may be collected and obtained through a plurality of manners.

In some embodiments, a phase of each pixel point in the first echo image and the second echo image may be extracted, respectively, to obtain a phase map corresponding to the first echo signal and a phase map corresponding to the second echo signal. Further, the magnetic field inhomogeneity map may be used to correct the phase map corresponding to each echo signal, so as to remove a baseline phase of each pixel point in the phase map (for example, the baseline phase δ in FIG. 5A or FIG. 5B), and then determine the phase difference of corresponding pixels in each echo signal phase map, thereby obtaining the corrected echo signal phase difference.

In the embodiments of the present disclosure, by determining the magnetic field inhomogeneity map and correcting the echo signal phase difference, an echo signal phase difference value only affected by a chemical shift effect of tissue components (for example, water and fat) is obtained, which improves the calculation accuracy.

Step 620, determining a first relational expression between a signal intensity of the second target component signal (S_{f}) and a target phase difference (Φ) based on the signal intensity of the first echo signal (a modulus of Sₚᵢₚ), the signal intensity of the second echo signal (a modulus of Sₚₒₚ), the echo signal phase difference (ΔΦ), the first component phase difference (θₚᵢₚ), and the second component phase difference (θₚₒₚ).

The target phase difference is a phase difference between the first target component signal and the first echo signal at the first echo time.

In some embodiments, the first relational expression may be determined based on the relational expression (4)-(8). The first relational expression is shown as the following relational expression (9):

$${S}_{f} = \frac{\begin{matrix}{S}_{pip} \cdot cos ( {ϕ}_{pip} + δ ) - \\ {S}_{pop} \cdot cos ( {ϕ}_{pop} + δ )\end{matrix}}{\begin{matrix}cos ( {θ}_{pip} + δ ) - \\ cos ( {θ}_{pop} + δ )\end{matrix}} = \frac{\begin{matrix}{S}_{pip} \cdot cos ( {ϕ}_{pip} + δ ) - \\ {S}_{pop} \cdot cos ( {ϕ}_{pip} + Δϕ + δ )\end{matrix}}{\begin{matrix}cos ( {θ}_{pip} + δ ) - \\ cos ( {θ}_{pop} + δ )\end{matrix}} . \qquad ( 9 )$$

In some embodiments, the value of the baseline phase δ does not affect the calculation result of the relational expression (9). Alternatively, the baseline phase δ has been removed after correction. Therefore, δ may be set to 0. In addition, by replacing Φₚᵢₚ with Φ, the relational expression (9) may be simplified to the following relational expression (10):

$${S}_{f} ( ϕ ) = \frac{{S}_{pip} \cdot cos ( ϕ ) - {S}_{pop} \cdot cos ( ϕ + Δϕ )}{cos ( {θ}_{pip} ) - cos ( {θ}_{pop} )} , \qquad ( 10 )$$

where S_{f}(Φ) is the second target component signal characterized based on Φ; the meaning of the other various parameters may refer to the relevant descriptions in the foregoing, for example, the descriptions related to FIG. 3.

It should be noted that, at the first echo time and the second echo time (for example, the first echo time and the second echo time shown in FIG. 5A to FIG. 5C), if the first target component signal S_{w} is in resonance (for example, by adjusting frequency of a radio frequency signal corresponding to the first echo signal and the second echo signal in an MRI sequence to be consistent with a precession frequency of protons of the first target component, so as to achieve that the first target component signal S_{w} is in resonance), then the baseline phase δ in these two echo signals (for example, the first echo signal and the second echo signal) is all fixed and equal, and does not change with time. Even if the first target component signal S_{w} is not in resonance, the baseline phase δ may change with time (for example, δ shown in FIG. 5A and FIG. 5B are not equal). Since when the first target component signal S_{w} is not in resonance, the modulus and the relative angle of the three vectors (S_{w}, S_{f}, and Sₚₒₚ) in FIG. 5B are the same as the modulus and the relative angle of the three vectors mentioned above in FIG. 5B when the first target component signal S_{w} is in resonance, subsequent calculations will not be affected. FIG. 5A also has similar characteristics. Based on this, in order to simplify calculations, δ in the relational expression (9) may be set to 0.

Step 630, determining a signal intensity constraint condition between the first target component signal and the second target component signal based on the signal intensity of the first echo signal, the signal intensity of the second echo signal, the first component phase difference, and the second component phase difference.

The signal intensity constraint condition refers to a limiting condition on the signal intensities of the first target component signal and the second target component signal.

In some embodiments, the signal intensity constraint condition includes a sum and difference of signal intensities of the first target component signal and the second target component signal.

In some embodiments, the processing device (for example, a processing device 110) or the third determination module 240 may determine the sum and difference of signal intensities of the first target component signal and the second target component signal based on the signal intensity of the first echo signal (the modulus of Sₚᵢₚ), the signal intensity of the second echo signal (the modulus of Sₚₒₚ), the first component phase difference (θₚᵢₚ), and the second component phase difference (θₚₒₚ).

In some embodiments, after Sₚᵢₚ, Sₚₒₚ, θₚᵢₚ, and θₚₒₚ have been determined, the larger one (hereinafter referred to as a larger signal) and the smaller one (hereinafter referred to as a smaller signal) of the two signals (namely the first target component signal and the second target component signal) may be calculated based on formula (11) and formula (12). However, it cannot be determined which of these two signals is the first target component signal and which is the second target component signal. Therefore, based on this, the signal intensity constraint condition may be obtained:

$${S}_{b} = \frac{1}{2} ( \sqrt{\frac{\begin{matrix}{S}_{pop}^{2} \cdot ( cos ( {θ}_{pip} ) - 1 ) - \\ {S}_{pip}^{2} \cdot ( cos ( {θ}_{pop} ) - 1 )\end{matrix}}{cos ( {θ}_{pip} ) - cos ( {θ}_{pop} )}} + \sqrt{\frac{\begin{matrix}{S}_{pop}^{2} \cdot ( cos ( {θ}_{pip} ) + 1 ) - \\ {S}_{pip}^{2} \cdot ( cos ( {θ}_{pop} ) + 1 )\end{matrix}}{cos ( {θ}_{pip} ) - cos ( {θ}_{pop} )}} ) , \qquad ( 11 )$$

$${S}_{s} = \frac{1}{2} ( \sqrt{\frac{\begin{matrix}{S}_{pop}^{2} \cdot ( cos ( {θ}_{pip} ) - 1 ) - \\ {S}_{pip}^{2} \cdot ( cos ( {θ}_{pop} ) - 1 )\end{matrix}}{cos ( {θ}_{pip} ) - cos ( {θ}_{pop} )}} - \sqrt{\frac{\begin{matrix}{S}_{pop}^{2} \cdot ( cos ( {θ}_{pip} ) + 1 ) - \\ {S}_{pip}^{2} \cdot ( cos ( {θ}_{pop} ) + 1 )\end{matrix}}{cos ( {θ}_{pip} ) - cos ( {θ}_{pop} )}} ) , \qquad ( 12 )$$

where S_{b} is the larger signal mentioned above; Sₛ is the smaller signal mentioned above; the meaning of the other parameters may refer to the relevant descriptions in the foregoing, for example, the descriptions related to FIG. 3.

Further, based on formula (11) and formula (12), the sum and difference of signal intensities mentioned above may be determined, as shown in formula (13) and formula (14):

Sᵢₚ=|S_{b}|+|Sₛ| (13),

Sₒₚ=∥S_{b}|−|Sₛ∥ (14),

where Sᵢₚ is the sum of signal intensities; and Sₒₚ is the difference of signal intensities.

Step 640, determining a relationship between a degree to which the signal intensity of the second target component signal satisfies the signal intensity constraint condition and the target phase difference based on the first relational expression and the signal intensity constraint condition.

In some embodiments, the above relationship may be characterized based on a discrepancy function, characterized by the target phase difference, between the difference between the signal intensity of the first target component signal and the signal intensity of the second target component signal, and the difference of signal intensities.

In some embodiments, the processing device (for example, the processing device 110) or the third determination module 240) may determine a second relational expression between the difference between the signal intensity of the first target component signal and the signal intensity of the second target component signal and the target phase difference based on the first relational expression (relational expression (10)) and the sum of signal intensities (Sᵢₚ); and determine the discrepancy function, characterized by the target phase difference, between the difference between the signal intensity of the first target component signal and the signal intensity of the second target component signal and the difference of signal intensities based on the second relational expression and the difference of signal intensities (Sₒₚ).

In some embodiments, the second relational expression is as shown in expression (15):

|S_{f}(Φ)−S_{w}(Φ)|² (15),

where S_{w}(Φ) is the second target component signal characterized based on Φ; the meaning of the other parameters may refer to the relevant description above.

Further, it can be known from formula (13) that S_{w}(Φ)=Sᵢₚ−S_{f}(Φ). By substituting this equation into expression (15), the second relational expression may be transformed into expression (16) as follows:

|2S_{f}(Φ)−Sᵢₚ|² (16).

In some embodiments, the above discrepancy function is as shown in expression (17):

|2S_{f}(Φ)−Sᵢₚ|²−|S_{b}−Sₛ|² (17).

Further, it can be known from formula (14) that

$${\vert {S}_{b} - {S}_{s} \vert}^{2} = {S}_{op}^{2} .$$

By substituting this equation into expression (17), the discrepancy function may be transformed into expression (18) as follows:

∥2S_{f}(Φ)−Sᵢₚ|²−|Sₒₚ|²| (18).

Step 650, determining a target value of the target phase difference that maximizes the degree to which the signal intensity of the second target component signal satisfies the signal intensity constraint condition.

Based on the discrepancy function shown in expression (18), it may be determined that the smaller the value of the discrepancy function, the greater the degree to which the signal intensity of the second target component signal satisfies the signal intensity constraint condition. In some embodiments, a value of a target phase difference that minimizes the discrepancy function may be determined as the target value. The above manner for determining the target value may be expressed by formula (19) as follows:

min_{Φ}{2S_{f}(Φ)−Sᵢₚ|²−|Sₒₚ|²} (19).

The solution of the above formula (19) is the target value of the target phase difference (denoted as Φₘ).

Step 660, determining the first target component fraction and the second target component fraction based on the target value of the target phase difference.

In some embodiments, the processing device (for example, a processing device 110) or the third determination module 240 may determine a signal intensity value of the second target component signal based on the first relational expression and the target value of the target phase difference; and determine the first target component fraction and the second target component fraction based on the signal intensity value of the second target component signal and the sum of signal intensities.

Specifically, by substituting the target value of the target phase difference (Φₘ) into the first relational expression, the signal intensity value of the second target component signal corresponding to the target value of the target phase difference is obtained, as shown in the following calculation process:

$${S}_{f} ( ϕ ) = \frac{\begin{matrix}{S}_{pip} \cdot cos ( ϕ ) - \\ {S}_{pop} \cdot cos ( ϕ + Δϕ )\end{matrix}}{cos ( {θ}_{pip} ) - cos ( {θ}_{pop} )} {⇒}^{ϕ = {ϕ}_{m}} {S}_{f} ( {ϕ}_{m} ) = \frac{\begin{matrix}{S}_{pip} \cdot cos ( {ϕ}_{m} ) - \\ {S}_{pop} \cdot cos ( {ϕ}_{m} + Δϕ )\end{matrix}}{cos ( {θ}_{pip} ) - cos ( {θ}_{pop} )} ,$$

where S_{f}(Φₘ) is the signal intensity value of the second target component signal corresponding to the target value of the target phase difference; the meaning of the other parameters may refer to the relevant description above.

In some embodiments, based on the above calculation result, the second target component fraction may be determined based on formula (20) as follows:

$$FF = \frac{{S}_{f} ( {ϕ}_{m} )}{{S}_{ip}} , \qquad ( 20 )$$

where FF is the second target component fraction.

Further, the first target component fraction may be determined based on formula (21) as follows:

WF=1−FF (21),

where WF is the first target component fraction.

In the embodiments of the present disclosure, by constructing the first relational expression between the signal intensity of the second target component signal and the target phase difference, combined with the signal intensity constraint condition, the target value of the target phase difference can be solved, and then an accurate target component fraction can be obtained.

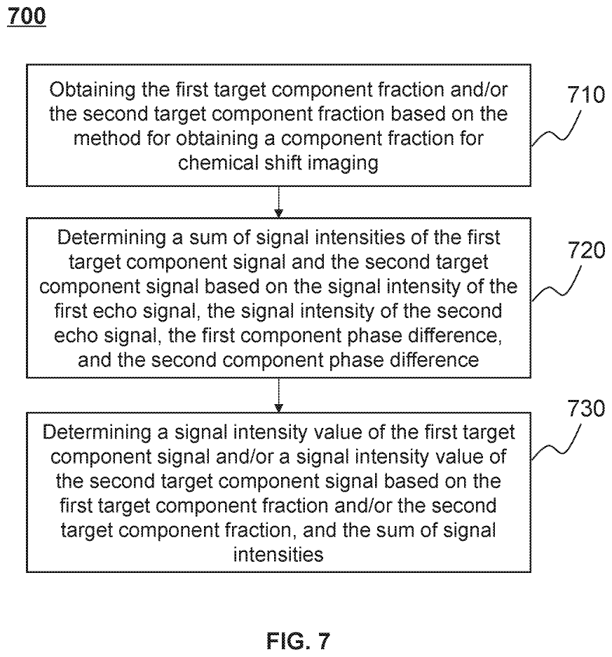

FIG. 7 is a flowchart illustrating an exemplary process for a chemical shift imaging method according to some embodiments of the present disclosure. As shown in FIG. 7, a process 700 includes the following steps. In some embodiments, the process 700 may be performed by the processing device (for example, the processing device 110).

Step 710, obtaining the first target component fraction and/or the second target component fraction based on the method for obtaining a component fraction for chemical shift imaging. More descriptions of the method for obtaining a component fraction for chemical shift imaging and the obtaining of the first target component fraction and/or the second target component fraction may be found in FIG. 3 or FIG. 6 and the relevant descriptions thereof.

As described above, in some embodiments, the first target component fraction and/or the second target component fraction corresponding to each pixel point may be obtained based on the first echo image and the second echo image.

Step 720, determining a sum of signal intensities of the first target component signal and the second target component signal based on the signal intensity of the first echo signal, the signal intensity of the second echo signal, the first component phase difference, and the second component phase difference.

In some embodiments, the following operations S1 and S2 may be performed on each pixel point in the first echo image and the second echo image, respectively, to determine the sum of signal intensities of the first target component signal and the second target component signal:
S1, obtaining the signal intensity of the first pixel point in the first echo image, and the signal intensity of the second pixel point in the second echo image corresponding to the first pixel point.
S2, obtaining the sum of signal intensities of the first target component signal and the second target component signal corresponding to the current pixel point based on the signal intensity of the first pixel point in the first echo image, the signal intensity of the corresponding second pixel point in the second echo image, the first component phase difference, and the second component phase difference.

It can be understood that, after performing the above operations on all pixel points of the first echo image and the second echo image, the sum of signal intensities corresponding to the respective pixel points in the first echo image or the second echo image may be obtained.

More descriptions regarding obtaining the sum of signal intensities of the first target component signal and the second target component signal may be found in FIG. 3 or FIG. 6 and the relevant descriptions thereof.

Step 730, determining a signal intensity value of the first target component signal and/or a signal intensity value of the second target component signal based on the first target component fraction and/or the second target component fraction, and the sum of signal intensities.

For example, for each pixel point in the first echo image or the second echo image, a product of the first target component fraction and the sum of signal intensities may be taken as the signal intensity value of the first target component signal, and a product of the second target component fraction and the sum of signal intensities may be taken as the signal intensity value of the second target component signal.

Further, after completing the above steps, the processing device (for example, the processing device 110) may merge to obtain a first target image based on the signal intensity value of the first target component signal of each pixel point in the first echo image or the second echo image; and merge to obtain a second target image based on the signal intensity value of the second target component signal of each pixel point in the first echo image or the second echo image.

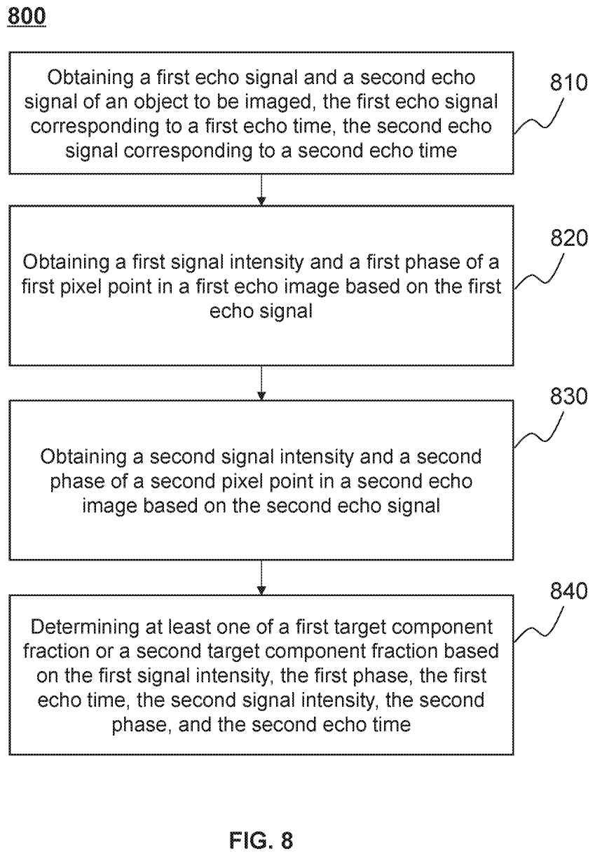

FIG. 8 is a flowchart illustrating an exemplary process for obtaining a component fraction for chemical shift imaging according to some embodiments of the present disclosure. As shown in FIG. 8, a process 800 includes the following steps. In some embodiments, the process 800 may be performed by a processing device (e.g., the processing device 110).

Step 810, obtaining a first echo signal and a second echo signal of an object to be imaged. The first echo signal corresponds to a first echo time, the second echo signal corresponds to a second echo time, and the second echo time is different from the first echo time.

More description regarding step 810 may be found in step 310 in FIG. 3 and the related description thereof.

Step 820, obtaining a first signal intensity and a first phase of a first pixel point in a first echo image based on the first echo signal.

In some embodiments, the processing device may reconstruct the first echo image based on the first echo signal. The first pixel point refers to a pixel point in the first echo image. The processing device may further obtain the first signal intensity and the first phase of the first pixel point based on the first echo image.

The first signal intensity of the first pixel point is also referred to as a signal intensity of the first pixel point or a signal intensity of the first echo signal, and the first phase is also referred to as a phase of a signal corresponding to the first pixel point or a phase of the first echo signal.

Step 830, obtaining a second signal intensity and a second phase of a second pixel point in a second echo image based on the second echo signal.

In some embodiments, the processing device may reconstruct the second echo image based on the second echo signal. The second pixel point refers to a pixel point in the second echo image. The processing device may further obtain the second signal intensity and the second phase of the second pixel point based on the second echo image.

The second signal intensity of the second pixel point is also referred to as a signal intensity of the second pixel point or a signal intensity of the second echo signa, and the second phase is also referred to as a phase of a signal corresponding to the second pixel point or a phase of the second echo signal.

More description regarding steps 820 and 830 may be found in steps 320 and 330 in FIG. 3 and the related description thereof.

Step 840, determining at least one of a first target component fraction or a second target component fraction based on the first signal intensity, the first phase, the first echo time, the second signal intensity, the second phase, and the second echo time.

In some embodiments, the determining at least one of the first target component fraction or the second target component fraction based on the first signal intensity, the first phase, the first echo time, the second signal intensity, the second phase, and the second echo time includes: determining an echo signal phase difference based on the first phase and the second phase; and determining at least one of the first target component fraction or the second target component fraction based on the echo signal phase difference, the first signal intensity, the first echo time, the second signal intensity, and the second echo time.

In some embodiments, the determining at least one of the first target component fraction or the second target component fraction based on the echo signal phase difference, the first signal intensity, the first echo time, the second signal intensity, and the second echo time includes determining a first component phase difference based on the first echo time and a precession frequency difference between a first target component and a second target component, wherein the first component phase difference reflects a phase difference between a first target component signal and a second target component signal at the first echo time; determining a second component phase difference based on the second echo time and the precession frequency difference, wherein the second component phase difference reflects a phase difference between the first target component signal and the second target component signal at the second echo time; and determining at least one of the first target component fraction or the second target component fraction based on the echo signal phase difference, the first signal intensity, the second signal intensity, the first component phase difference, and the second component phase difference.

In some embodiments, the determining at least one of the first target component fraction or the second target component fraction based on the echo signal phase difference, the first signal intensity, the second signal intensity, the first component phase difference, and the second component phase difference includes determining a first relational expression of a signal intensity of the second target component signal and a target phase difference based on the echo signal phase difference, the first signal intensity, the second signal intensity, the first component phase difference, and the second component phase difference, wherein the target phase difference is a phase difference between the first target component signal and the first echo signal at the first echo time; determining a signal intensity constraint condition of the first target component signal and the second target component signal based on the first signal intensity, the second signal intensity, the first component phase difference, and the second component phase difference; determining a relationship between a degree to which the signal intensity of the second target component signal satisfies the signal intensity constraint condition and the target phase difference based on the first relational expression and the signal intensity constraint condition; determining a target value of the target phase difference that maximizes the degree to which the signal intensity of the second target component signal satisfies the signal intensity constraint condition; and determining at least one of the first target component fraction or the second target component fraction based on the target value of the target phase difference.

More description regarding steps 840 may be found in step 340 in FIG. 3, FIG. 6, and the related description thereof.

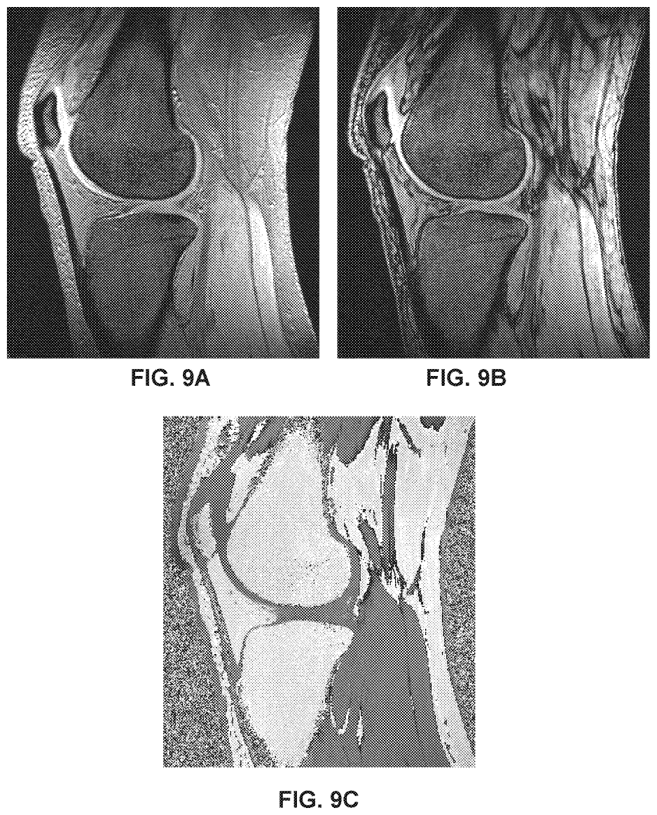

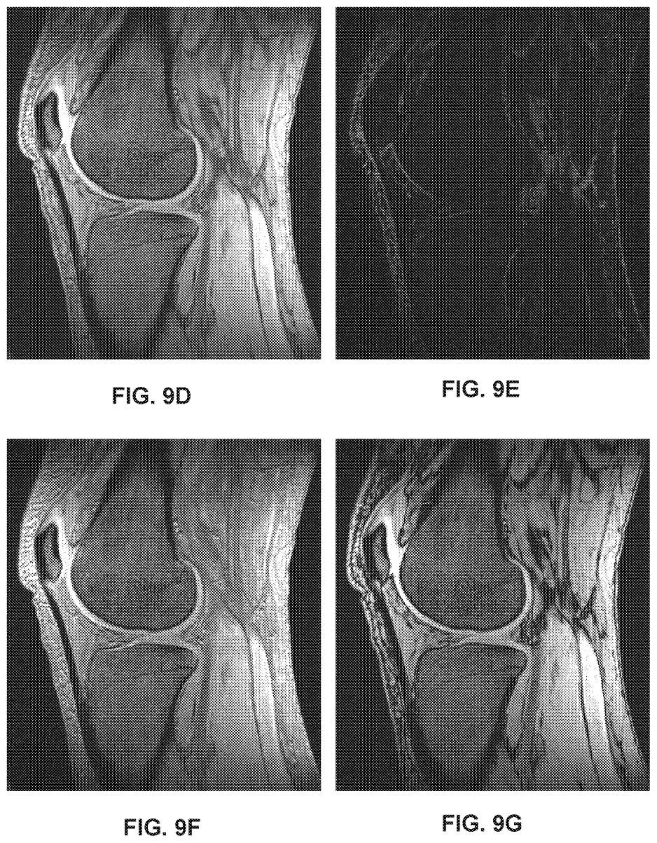

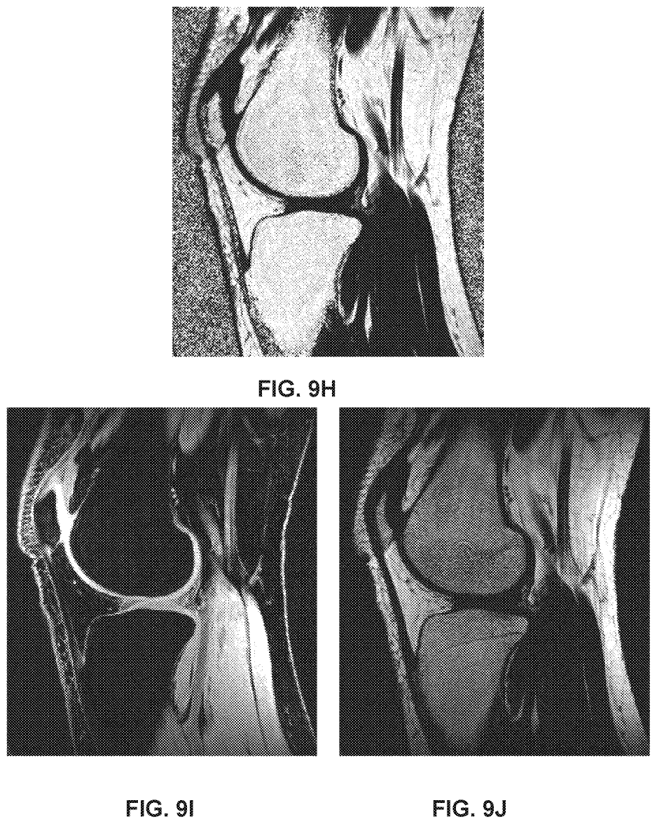

FIG. 9A is a schematic diagram illustrating a first echo image according to some embodiments of the present disclosure. FIG. 9B is a schematic diagram illustrating a second echo image according to some embodiments of the present disclosure.

For example, the first echo image shown in FIG. 9A is an image reconstructed based on the first echo signal of the object to be imaged, and the second echo image shown in FIG. 9B is an image reconstructed based on the second echo signal of the object to be imaged.

FIG. 9C is a schematic diagram illustrating an image corresponding to a target phase difference according to some embodiments of the present disclosure.

For example, a phase of a signal corresponding to each pixel in the image shown in FIG. 9C is a difference between a phase of a signal corresponding to the first pixel that corresponds to the pixel (e.g., having the same position coordinates in the image it belongs to) and a phase of a signal corresponding to the second pixel that corresponds to the pixel.

FIG. 9D is a schematic diagram illustrating an image corresponding to a larger signal according to some embodiments of the present disclosure. FIG. 9E is a schematic diagram illustrating an image corresponding to a smaller signal according to some embodiments of the present disclosure.

For example, the image shown in FIG. 9D is an image reconstructed based on the larger signal. A pixel value of each pixel in the image shown in FIG. 9D represents the larger one (i.e., the larger signal) of the first target component signal and the second target component signal corresponding to the first pixel or the second pixel that corresponds to the pixel. The image shown in FIG. 9E is an image reconstructed based on the smaller signal. A pixel value of each pixel in the image shown in FIG. 9E represents the smaller one (i.e., the smaller signal) of the first target component signal and the second target component signal corresponding to the first pixel or the second pixel that corresponds to the pixel.

FIG. 9F is a schematic diagram illustrating an image corresponding to a sum of signal intensities according to some embodiments of the present disclosure. FIG. 9G is a schematic diagram illustrating an image corresponding to a difference of signal intensities according to some embodiments of the present disclosure.

For example, the image shown in FIG. 9F is an image reconstructed based on the sum of signal intensities of the first target component signal and the second target component signal (e.g., the sum of the larger signal and the smaller signal mentioned above), and the image shown in FIG. 9G is an image reconstructed based on the difference of signal intensities of the first target component signal and the second target component signal (e.g., the difference between the larger signal and the smaller signal mentioned above).

FIG. 9H is a schematic diagram illustrating the second target component fraction according to some embodiments of the present disclosure.

For example, a pixel value of each pixel in the image shown in FIG. 9H represents the second target component fraction of each pixel in the corresponding first echo image or the second echo image.

FIG. 9I is a schematic diagram illustrating a first target image according to some embodiments of the present disclosure. FIG. 9J is a schematic diagram illustrating a second target image according to some embodiments of the present disclosure.

As shown in FIG. 9I, a pixel value of each pixel in the first target image respectively represents a signal intensity value of the first target component signal of each pixel in the corresponding first echo image or the second echo image; as shown in FIG. 9J, a pixel value of each pixel in the second target image respectively represents a signal intensity value of the second target component signal of each pixel in the corresponding first echo image or the second echo image.

Having thus described the basic concepts, it may be rather apparent to those skilled in the art after reading this detailed disclosure that the foregoing detailed disclosure is intended to be presented by way of example only and is not limiting. Various alterations, improvements, and modifications may occur and are intended to those skilled in the art, though not expressly stated herein. These alterations, improvements, and modifications are intended to be suggested by this disclosure, and are within the spirit and scope of the exemplary embodiments of this disclosure.

Moreover, certain terminology has been used to describe embodiments of the present disclosure. For example, the terms “one embodiment,” “an embodiment,” and/or “some embodiments” may mean that a particular feature, structure or characteristic described in connection with the embodiment is included in at least one embodiment of the present disclosure. Therefore, it is emphasized and should be appreciated that two or more references to “an embodiment” or “one embodiment” or “an alternative embodiment” in various portions of this specification are not necessarily all referring to the same embodiment. Furthermore, the particular features, structures, or characteristics may be combined as suitable in one or more embodiments of the present disclosure.

Furthermore, the recited order of processing elements or sequences, or the use of numbers, letters, or other designations therefore, is not intended to limit the claimed processes and methods to any order except as may be specified in the claims. Although the above disclosure discusses through various examples what is currently considered to be a variety of useful embodiments of the disclosure, it is to be understood that such detail is solely for that purpose, and that the appended claims are not limited to the disclosed embodiments, but, on the contrary, are intended to cover modifications and equivalent arrangements that are within the spirit and scope of the disclosed embodiments. For example, although the implementation of various components described above may be embodied in a hardware device, it may also be implemented as a software only solution, for example, an installation on an existing server or mobile device.

Similarly, it should be appreciated that in the foregoing description of embodiments of the present disclosure, various features are sometimes grouped together in a single embodiment, figure, or description thereof for the purpose of streamlining the disclosure aiding in the understanding of one or more of the various inventive embodiments. This method of disclosure, however, is not to be interpreted as reflecting an intention that the claimed object matter requires more features than are expressly recited in each claim. Rather, inventive embodiments lie in less than all features of a single foregoing disclosed embodiment.

In some embodiments, the numbers expressing quantities or properties used to describe and claim certain embodiments of the application are to be understood as being modified in some instances by the term “about,” “approximate,” or “substantially.” For example, “about,” “approximate,” or “substantially” may indicate ±1%, ±5%, ±10%, or ±20% variation of the value it describes, unless otherwise stated. Accordingly, in some embodiments, the numerical parameters set forth in the written description and attached claims are approximations that may vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the application are approximations, the numerical values set forth in the specific examples are reported as precisely as practicable.

Each of the patents, patent applications, publications of patent applications, and other material, such as articles, books, specifications, publications, documents, things, and/or the like, referenced herein is hereby incorporated herein by this reference in its entirety for all purposes, excepting any prosecution file history associated with same, any of same that is inconsistent with or in conflict with the present document, or any of same that may have a limiting effect as to the broadest scope of the claims now or later associated with the present document. By way of example, should there be any inconsistency or conflict between the description, definition, and/or the use of a term associated with any of the incorporated material and that associated with the present document, the description, definition, and/or the use of the term in the present document shall prevail.

In closing, it is to be understood that the embodiments of the application disclosed herein are illustrative of the principles of the embodiments of the application. Other modifications that may be employed may be within the scope of the application. Thus, by way of example, but not of limitation, alternative configurations of the embodiments of the application may be utilized in accordance with the teachings herein. Accordingly, embodiments of the present application are not limited to that precisely as shown and described.

What is claimed is:

1. A method for obtaining a component fraction for chemical shift imaging, comprising:
obtaining one or more echo signal pairs of an object to be imaged, wherein each echo signal pair includes a first echo signal and a second echo signal, the first echo signal corresponds to a first echo time, the second echo signal corresponds to a second echo time, and the second echo time is different from the first echo time; and
performing following processing on at least one echo signal pair of the one or more echo signal pairs to obtain at least one of a first target component fraction or a second target component fraction corresponding to the at least one echo signal pair:
determining a first component phase difference based on the first echo time and a precession frequency difference between a first target component signal and a second target component signal of the at least one echo signal pair, wherein the first component phase difference reflects a phase difference between the first target component signal and the second target component signal at the first echo time;
determining a second component phase difference based on the second echo time and the precession frequency difference, wherein the second component phase difference reflects a phase difference between the first target component signal and the second target component signal at the second echo time; and
determining the at least one of the first target component fraction or the second target component fraction based on a signal intensity and a phase of the first echo signal, a signal intensity and a phase of the second echo signal, the first component phase difference, and the second component phase difference.

2. The method according to claim 1, wherein the first echo time is closer to an in-phase echo time than the second echo time, and the second echo time is closer to an opposed-phase echo time than the first echo time, wherein the in-phase echo time is an in-phase echo time of the first target component signal and the second target component signal, and the opposed-phase echo time is an opposed-phase echo time of the first target component signal and the second target component signal.

3. The method according to claim 2, wherein the determining the at least one of the first target component fraction or the second target component fraction based on a signal intensity and a phase of the first echo signal, a signal intensity and a phase of the second echo signal, the first component phase difference, and the second component phase difference includes:
determining an echo signal phase difference based on a difference between the phase of the first echo signal and the phase of the second echo signal;
determining a first relational expression of a signal intensity of the second target component signal and a target phase difference based on the signal intensity of the first echo signal, the signal intensity of the second echo signal, the echo signal phase difference, the first component phase difference, and the second component phase difference, wherein the target phase difference is a phase difference between the first target component signal and the first echo signal at the first echo time;
determining a signal intensity constraint condition of the first target component signal and the second target component signal based on the signal intensity of the first echo signal, the signal intensity of the second echo signal, the first component phase difference, and the second component phase difference;
determining a relationship between a degree to which the signal intensity of the second target component signal satisfies the signal intensity constraint condition and the target phase difference based on the first relational expression and the signal intensity constraint condition;
determining a target value of the target phase difference that maximizes the degree to which the signal intensity of the second target component signal satisfies the signal intensity constraint condition; and
determining the first target component fraction and the second target component fraction based on the target value of the target phase difference.

4. The method according to claim 3, wherein the determining a signal intensity constraint condition of the first target component signal and the second target component signal based on the signal intensity of the first echo signal, the signal intensity of the second echo signal, the first component phase difference, and the second component phase difference includes:
determining a sum and difference of signal intensities of the first target component signal and the second target component signal based on the signal intensity of the first echo signal, the signal intensity of the second echo signal, the first component phase difference, and the second component phase difference, wherein the signal intensity constraint condition includes the sum and difference of signal intensities.

5. The method according to claim 4, wherein
the determining a relationship between a degree to which the signal intensity of the second target component signal satisfies the signal intensity constraint condition and the target phase difference based on the first relational expression and the signal intensity constraint condition includes:
determining a second relational expression of a difference between the signal intensity of the first target component signal and the signal intensity of the second target component signal and the target phase difference based on the first relational expression and the sum of signal intensities; and
determining a discrepancy function, characterized by the target phase difference, between the difference between the signal intensity of the first target component signal and the signal intensity of the second target component signal and the difference of signal intensities based on the second relational expression and the difference of signal intensities;
wherein the determining a target value of the target phase difference that maximizes the degree to which the signal intensity of the second target component signal satisfies the signal intensity constraint condition includes:
determining a value of the target phase difference that minimizes the discrepancy function as the target value.

6. The method according to claim 5, wherein the determining the first target component fraction and the second target component fraction based on the target value of the target phase difference includes:
determining a signal intensity value of the second target component signal based on the first relational expression and the target value of the target phase difference; and
determining the first target component fraction and the second target component fraction based on the signal intensity value of the second target component signal and the sum of signal intensities.

7. The method according to claim 3, wherein the echo signal phase difference is corrected by a magnetic field inhomogeneity map.

8. The method according to claim 1, wherein a first target component and a second target component respectively corresponding to the first target component signal and the second target component signal are different and are respectively one of water, fat, and silicone.

9. The method according to claim 1, wherein
the first echo signal is obtained based on a first MRI sequence, and the second echo signal is obtained based on a second MRI sequence; or
the first echo signal is obtained based on a sampled signal at a first time of a third MRI sequence, and the second echo signal is obtained based on a sampled signal at a second time of the third MRI sequence.

10. The method according to claim 1, further comprising at least one of:
performing a statistical calculation on the first target component fraction corresponding to the at least one echo signal pair to obtain a statistical value of the first target component fraction; or
performing a statistical calculation on the second target component fraction corresponding to the at least one echo signal pair to obtain a statistical value of the second target component fraction.

11. A device for obtaining a component fraction for chemical shift imaging, comprising:
at least one storage device storing an instruction set; and
at least one processor in communication with the at least one storage device, wherein when the instruction set is executed, the at least one processor is configured to perform operations comprising:
obtaining one or more echo signal pairs of an object to be imaged, wherein each echo signal pair includes a first echo signal and a second echo signal, the first echo signal corresponds to a first echo time, the second echo signal corresponds to a second echo time, and the second echo time is different from the first echo time; and
performing following processing on at least one echo signal pair of the one or more echo signal pairs to obtain at least one of a first target component fraction or a second target component fraction corresponding to the at least one echo signal pair:
determining a first component phase difference based on the first echo time and a precession frequency difference between a first target component signal and a second target component signal of the at least one echo signal pair, wherein the first component phase difference reflects a phase difference between the first target component signal and the second target component signal at the first echo time;
determining a second component phase difference based on the second echo time and the precession frequency difference, wherein the second component phase difference reflects a phase difference between the first target component signal and the second target component signal at the second echo time; and
determining the at least one of the first target component fraction or the second target component fraction based on a signal intensity and a phase of the first echo signal, a signal intensity and a phase of the second echo signal, the first component phase difference, and the second component phase difference.

12. The device according to claim 11, wherein the first echo time is closer to an in-phase echo time than the second echo time, and the second echo time is closer to an opposed-phase echo time than the first echo time, wherein the in-phase echo time is an in-phase echo time of the first target component signal and the second target component signal, and the opposed-phase echo time is an opposed-phase echo time of the first target component signal and the second target component signal.

13. The device according to claim 12, wherein the determining the at least one of the first target component fraction or the second target component fraction based on a signal intensity and a phase of the first echo signal, a signal intensity and a phase of the second echo signal, the first component phase difference, and the second component phase difference includes:
determining an echo signal phase difference based on a difference between the phase of the first echo signal and the phase of the second echo signal;
determining a first relational expression of a signal intensity of the second target component signal and a target phase difference based on the signal intensity of the first echo signal, the signal intensity of the second echo signal, the echo signal phase difference, the first component phase difference, and the second component phase difference, wherein the target phase difference is a phase difference between the first target component signal and the first echo signal at the first echo time;
determining a signal intensity constraint condition of the first target component signal and the second target component signal based on the signal intensity of the first echo signal, the signal intensity of the second echo signal, the first component phase difference, and the second component phase difference;
determining a relationship between a degree to which the signal intensity of the second target component signal satisfies the signal intensity constraint condition and the target phase difference based on the first relational expression and the signal intensity constraint condition;
determining a target value of the target phase difference that maximizes the degree to which the signal intensity of the second target component signal satisfies the signal intensity constraint condition; and
determining the first target component fraction and the second target component fraction based on the target value of the target phase difference.

14. The device according to claim 13, wherein the determining a signal intensity constraint condition of the first target component signal and the second target component signal based on the signal intensity of the first echo signal, the signal intensity of the second echo signal, the first component phase difference, and the second component phase difference includes:
determining a sum and difference of signal intensities of the first target component signal and the second target component signal based on the signal intensity of the first echo signal, the signal intensity of the second echo signal, the first component phase difference, and the second component phase difference, wherein the signal intensity constraint condition includes the sum and difference of signal intensities.

15. The device according to claim 14, wherein
the determining a relationship between a degree to which the signal intensity of the second target component signal satisfies the signal intensity constraint condition and the target phase difference based on the first relational expression and the signal intensity constraint condition includes:
determining a second relational expression of a difference between the signal intensity of the first target component signal and the signal intensity of the second target component signal and the target phase difference based on the first relational expression and the sum of signal intensities; and
determining a discrepancy function, characterized by the target phase difference, between the difference between the signal intensity of the first target component signal and the signal intensity of the second target component signal and the difference of signal intensities based on the second relational expression and the difference of signal intensities;
wherein the determining a target value of the target phase difference that maximizes the degree to which the signal intensity of the second target component signal satisfies the signal intensity constraint condition includes:
determining a value of the target phase difference that minimizes the discrepancy function as the target value.

16. The device according to claim 15, wherein the determining the first target component fraction and the second target component fraction based on the target value of the target phase difference includes:
determining a signal intensity value of the second target component signal based on the first relational expression and the target value of the target phase difference; and
determining the first target component fraction and the second target component fraction based on the signal intensity value of the second target component signal and the sum of signal intensities.

17. A method for obtaining a component fraction for chemical shift imaging, comprising:
obtaining a first echo signal and a second echo signal of an object to be imaged, wherein the first echo signal corresponds to a first echo time, the second echo signal corresponds to a second echo time, and the second echo time is different from the first echo time;
obtaining a first signal intensity and a first phase of a first pixel point in a first echo image based on the first echo signal;
obtaining a second signal intensity and a second phase of a second pixel point in a second echo image based on the second echo signal; and
determining at least one of a first target component fraction or a second target component fraction based on the first signal intensity, the first phase, the first echo time, the second signal intensity, the second phase, and the second echo time.

18. The method according to claim 17, wherein the determining at least one of the first target component fraction or the second target component fraction based on the first signal intensity, the first phase, the first echo time, the second signal intensity, the second phase, and the second echo time includes:
determining an echo signal phase difference based on the first phase and the second phase; and
determining at least one of the first target component fraction or the second target component fraction based on the echo signal phase difference, the first signal intensity, the first echo time, the second signal intensity, and the second echo time.

19. The method according to claim 18, wherein the determining at least one of the first target component fraction or the second target component fraction based on the echo signal phase difference, the first signal intensity, the first echo time, the second signal intensity, and the second echo time includes:
determining a first component phase difference based on the first echo time and a precession frequency difference between a first target component and a second target component, wherein the first component phase difference reflects a phase difference between a first target component signal and a second target component signal at the first echo time;
determining a second component phase difference based on the second echo time and the precession frequency difference, wherein the second component phase difference reflects a phase difference between the first target component signal and the second target component signal at the second echo time; and
determining at least one of the first target component fraction or the second target component fraction based on the echo signal phase difference, the first signal intensity, the second signal intensity, the first component phase difference, and the second component phase difference.

20. The method according to claim 19, wherein the determining at least one of the first target component fraction or the second target component fraction based on the echo signal phase difference, the first signal intensity, the second signal intensity, the first component phase difference, and the second component phase difference includes:
determining a first relational expression of a signal intensity of the second target component signal and a target phase difference based on the echo signal phase difference, the first signal intensity, the second signal intensity, the first component phase difference, and the second component phase difference, wherein the target phase difference is a phase difference between the first target component signal and the first echo signal at the first echo time;
determining a signal intensity constraint condition of the first target component signal and the second target component signal based on the first signal intensity, the second signal intensity, the first component phase difference, and the second component phase difference;
determining a relationship between a degree to which the signal intensity of the second target component signal satisfies the signal intensity constraint condition and the target phase difference based on the first relational expression and the signal intensity constraint condition;
determining a target value of the target phase difference that maximizes the degree to which the signal intensity of the second target component signal satisfies the signal intensity constraint condition; and
determining at least one of the first target component fraction or the second target component fraction based on the target value of the target phase difference.
